(19) United States
(12) Patent Application Publication
(10) Pub. No.: US 2026/0095152 A1
(43) Pub. Date: Apr. 2, 2026

(54) REFLECTIVE TRANSMISSION LINE WITH NEGATIVE IMPEDANCE CELLS

(71) Applicant: TEXAS INSTRUMENTS INCORPORATED, Dallas, TX (US)

(72) Inventors: Sidharth THOMAS, Dallas, TX (US); Sachin KALIA, Richardson, TX (US); Tolga DINC, Dallas, TX (US); Swaminathan SANKARAN, Allen, TX (US)

(21) Appl. No.: 18/901,259

(22) Filed: Sep. 30, 2024

(51) Int. Cl. H03H 11/16; H04B 1/40

(52) U.S. Cl. CPC H03H 11/16; H04B 1/40

(57) ABSTRACT

An integrated circuit includes a transmission line including bandpass units. Each bandpass unit includes: a first inductor having a first terminal and a second terminal; a second inductor having a first terminal and a second terminal, the first inductor and the second inductor forming a transformer; a first capacitor having a first terminal and a second terminal, the first terminal of the first capacitor coupled to the first terminal of the first inductor, and the second terminal of the first capacitor coupled to the second terminal of the first inductor; and a second capacitor having a first terminal and a second terminal, the first terminal of the second capacitor coupled to the first terminal of the second inductor, and the second terminal of the second capacitor coupled to the second terminal of the second inductor.

### BACKGROUND

Integrated circuit (IC) transmission lines may be used in radio frequency/microwave circuits and affect passive design, impedance matching, and IC size. Such transmission lines can perform signal filtering operations, such as lowpass filtering or bandpass filtering. Crosstalk between reflective cells of a transmission line can result in reduced speeds and reduced accuracy. Some switches are frequency limited, which their use in a reflective cell.

### SUMMARY

In an example, an integrated circuit includes a transmission line including bandpass units. Each bandpass unit includes: a first inductor having a first terminal and a second terminal; a second inductor having a first terminal and a second terminal, the first inductor and the second inductor forming a transformer; a first capacitor having a first terminal and a second terminal, the first terminal of the first capacitor coupled to the first terminal of the first inductor, and the second terminal of the first capacitor coupled to the second terminal of the first inductor; and a second capacitor having a first terminal and a second terminal, the first terminal of the second capacitor coupled to the first terminal of the second inductor, and the second terminal of the second capacitor coupled to the second terminal of the second inductor.

In another example, a phase shifter includes reflection-type phase shifter circuitry. The reflection-type phase shifter circuitry includes: a first distributed reflective load including first negative impedance cells; a second distributed reflective load including second negative impedance cells; and an I/Q generator having a first terminal, a second terminal, a third terminal, and a fourth terminal. The second terminal of the I/Q generator is coupled to the first distributed reflective load. The third terminal of the I/Q generator is coupled to the second distributed reflective load.

In yet another example, an apparatus includes: a processor; transceiver circuitry coupled to the processor, and antenna array terminals coupled to the transceiver circuitry. The transceiver circuitry includes bidirectional phase shifter circuitry. The bidirectional phase shifter circuitry includes: a first distributed reflective load including first negative impedance cells; a second distributed reflective load including second negative impedance cells; and an I/Q generator having a first terminal, a second terminal, a third terminal, and a fourth terminal. The second terminal of the I/Q generator is coupled to the first distributed reflective load. The third terminal of the I/Q generator is coupled to the second distributed reflective load.

### BRIEF DESCRIPTION OF THE DRAWINGS

FIG. 1 is a diagram showing an example system.

FIG. 2 is a diagram showing another example system.

FIG. 3 is a diagram showing an example transceiver.

FIG. 4 is a diagram showing an example distributed reflective load (DRL) with negative impedance cells.

FIGS. 5A to 5E are schematic diagrams showing example negative impedance cells.

FIGS. 6A to 6F are schematic diagrams showing other example negative impedance cells.

FIG. 7 is a schematic diagram showing another example negative impedance cell.

FIGS. 8A to 8C are schematic diagrams showing example transmission lines.

FIG. 9 is a diagram showing a double-tuned transformer-based bandpass unit.

FIG. 10 is a graph showing S-parameters of a phase shifter as a function of frequency for different control settings.

FIGS. 11 and 12 are diagrams showing example phase shifters.

### DETAILED DESCRIPTION

The same reference numbers or other reference designators are used in the drawings to designate the same or similar features. Such features may be the same or similar either by function and/or structure.

In the described examples, transmission lines with negative impedance cells are used to provide distributed reflective load (DRL) functionality. As used herein “negative impedance cells” refer to circuits that respond to a positive voltage excitation at the input with a negative current, or that respond to a negative voltage excitation at the input with a positive current (i.e., current and voltage are 180 degrees out of phase). Each transmission line may provide lowpass filtering or bandpass filtering. In some examples, each transmission line is a double-tuned transformer-based bandpass transmission line, which prevents crosstalk between the negative impedance cells. In some examples, the transmission lines provide passive functional or impedance matching for radio frequency/microwave applications (e.g., pass amplifier, filters, etc.).

In some examples, the transmission lines are part of a phase shifter or related integrated circuit (IC) such as a transceiver IC. An example phase shifter includes a first transmission line with first negative impedance cells; a second transmission line with second negative impedance cells; and an I/Q generator having a first terminal, a second terminal, a third terminal, and a fourth terminal. The second terminal of the I/Q generator is coupled to the first transmission line. The third terminal of the I/Q generator is coupled to the second transmission line. In some examples, phase shifters are used for radar or phased array communications (e.g., Satcom/5G) to control orthogonal phase and amplitude, which reduces calibration complexity for beam-steering and sidelobe suppression. In some examples, phase shifters are passive phase shifters supporting bidirectional operation, which simplifies beamformer architecture. In some examples, phase shifters are bidirectional “calibration-free” low-loss phase shifters with low root-means-square (RMS) amplitude and phase errors. In some examples, phase shifters are based on true time delay options to support broadband operations.

In some examples, phase shifters operate at frequencies (e.g., above 77 GHz) where switches cannot be designed. In such examples, phase shifters include one or more of the following: a DRL with active open switch; or a DRL with active short switch circuits. Each active open switch circuit emulates an open circuit along the transmission line of a DRL. Each active short switch circuit emulates a short circuit along the transmission line of a DRL.

In one example, a phase shifter is a bidirectional active reflection-type phase shifter (RTPS) with DRL. In some examples, DRL functionality provided by negative impedance cells supports embedded phase inversion. In some examples, a negative impedance cell has phase inversion states including 0 and 180 degrees. In some examples, a negative impedance cell has phase inversion states including 0 and 360 degrees. In some examples, the impedance of each negative impedance cell is adjustable to match to different impedance values (e.g., 500, 100Ω, etc.).

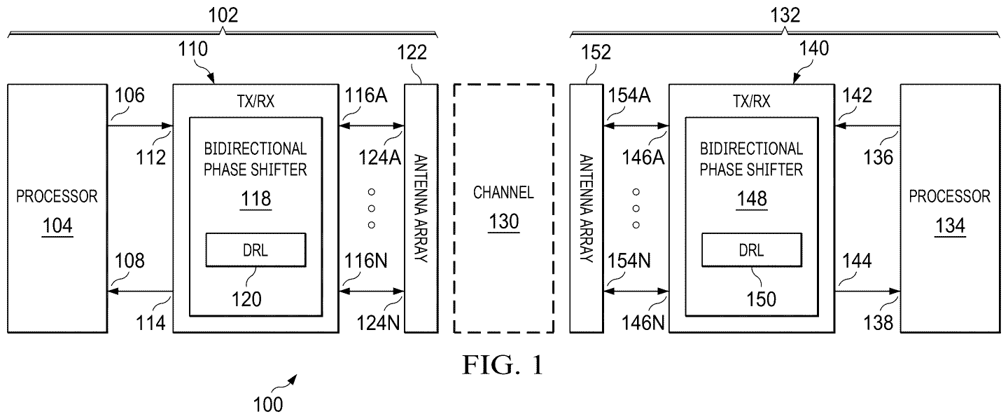

FIG. 1 is a diagram showing an example system 100. The system 100 is an example of a phased array communication system (e.g., a Satcom or 5G system). The system 100 includes a first device 102 in communication with a second device 132 via a channel 130. In the example of FIG. 1, the channel 130 is a wireless channel. The first and second devices 102 and 132 are phased array communication units.

As shown, the first device 102 includes a processor 104, a transceiver 110, and an antenna array 122. The processor 104 has a first terminal 106 and a second terminal 108. In some examples, the first terminal 106 and the second terminal 108 are unidirectional terminals. In other examples, a bidirectional terminal replaces the first terminal 106 and the second terminal 108. The transceiver 110 has a first terminal 112, a second terminal 114, and third terminals 116A to 116N. In some examples, the first terminal 112 and the second terminal 114 are unidirectional terminals. In other examples, a bidirectional terminal replaces the first terminal 112 and the second terminal 114. The antenna array 122 has terminals 124A to 124N. In the example of FIG. 1, the transceiver 110 includes a bidirectional phase shifter 118 with a DRL 120. In some examples, the DRL 120 is based on a transmission line with negative impedance cells as described herein.

The second device 132 includes a processor 134, a transceiver 140, and an antenna array 152. The second device 132 includes a processor 134, a transceiver 140, and an antenna array 152. The processor 134 has a first terminal 136 and a second terminal 138. In some examples, the first terminal 136 and the second terminal 138 are unidirectional terminals. In other examples, a bidirectional terminal replaces the first terminal 136 and the second terminal 138. The transceiver 140 has a first terminal 142, a second terminal 144, and third terminals 146A to 146N. In some examples, the first terminal 142 and the second terminal 144 are unidirectional terminals. In other examples, a bidirectional terminal replaces the first terminal 142 and the second terminal 144. The antenna array 152 has terminals 154A to 154N. In the example of FIG. 1, the transceiver 140 includes a bidirectional phase shifter 148 with a DRL 150. In some examples, the DRL 150 is based on a transmission line with negative impedance cells as described herein.

The first terminal 106 of the processor 104 is coupled to the first terminal 112 of the transceiver 110. The second terminal 108 of the processor 104 is coupled to the second terminal 114 of the transceiver 110. Each terminal of the third terminals 116A to 116N of the transceiver 110 is coupled to a respective terminal of the terminals 124A to 124N of the antenna array 122.

The first terminal 136 of the processor 134 is coupled to the first terminal 142 of the transceiver 140. The second terminal 138 of the processor 134 is coupled to the second terminal 144 of the transceiver 140. Each terminal of the third terminals 146A to 146N of the transceiver 140 is coupled to a respective terminal of the terminals 154A to 154N of the antenna array 152.

During data transmission operations, the first device 102 operates to: generate data using the processor 104; encode the data for transmission using the transceiver 110; and transmit the encoded data to the channel 130 via the antenna array 122. In some examples, data (before or after encoding) is phase shifted for each antenna of the antenna array 122 using the bidirectional phase shifter 118 with the DRL 120.

During data reception operations, the first device 102 operates to: receive encoded data via the channel 130 using the antenna array 122; decode the encoded data using the transceiver 110; and process the decoded data using the processor 104. In some examples, data (before or after decoding) from each antenna of the antenna array 122 is phase shifted using the bidirectional phase shifter 118 with the DRL 120.

During data transmission operations, the second device 132 operates to: generate data using the processor 134; encode the data for transmission using the transceiver 140; and transmit the encoded data to the channel 130 via the antenna array 152. In some examples, data (before or after encoding) is phase shifted for each antenna of the antenna array 152 using the bidirectional phase shifter 148 with the DRL 150.

During data reception operations, the second device 132 operates to: receive encoded data via the channel 130 using the antenna array 152; decode the encoded data using the transceiver 140; and process the decoded data using the processor 134. In some examples, data (before or after decoding) from each antenna of the antenna array 152 is phase shifted using the bidirectional phase shifter 148 with the DRL 150.

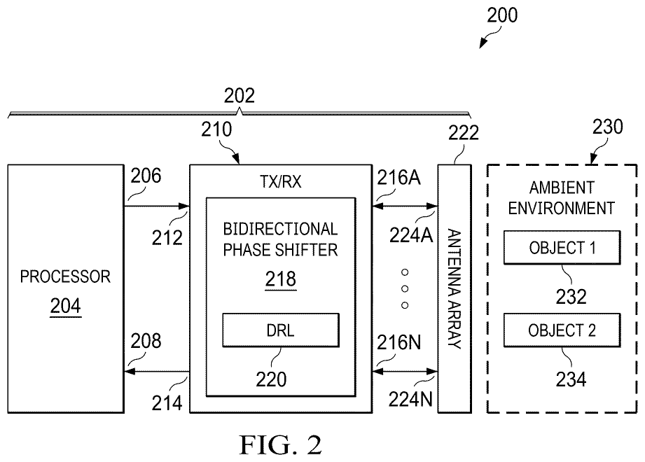

FIG. 2 is a diagram showing another example system. The system 200 is an example of a radar system. The system 200 includes a device 202. In some examples, the device 202 is a phased array communication unit. In the example of FIG. 2, the device 202 operates to: transmit electromagnetic signals; receive reflections from objects in an ambient environment 230; and determine parameters (e.g., location, velocity) of the objects. In the example of FIG. 2, a first object 232 and a second object 234 are represented in the ambient environment 230.

As shown, the device 202 includes a processor 204, a transceiver 210, and an antenna array 222. The processor 204 has a first terminal 206 and a second terminal 208. In some examples, the first terminal 206 and the second terminal 208 are unidirectional terminals. In other examples, a bidirectional terminal replaces the first terminal 206 and the second terminal 208. The transceiver 210 has a first terminal 212, a second terminal 214, and third terminals 216A to 216N. In some examples, the first terminal 212 and the second terminal 214 are unidirectional terminals. In other examples, a bidirectional terminal replaces the first terminal 212 and the second terminal 214. The antenna array 222 has terminals 224A to 224N. In the example of FIG. 2, the transceiver 210 includes a bidirectional phase shifter 218 with a DRL 220. In some examples, the DRL 220 is based on a transmission line with negative impedance cells as described herein.

The first terminal 206 of the processor 204 is coupled to the first terminal 212 of the transceiver 210. The second terminal 208 of the processor 204 is coupled to the second terminal 214 of the transceiver 210. Each terminal of the third terminals 216A to 216N of the transceiver 210 is coupled to a respective terminal of the terminals 224A to 224N of the antenna array 222.

During signal transmit operations, the device 202 operates to: generate instructions using the processor 204; prepare signals or signal patterns for transmission using the transceiver 210 responsive to the instructions; and transmit the prepared signals or signal patterns to the ambient environment 230 via the antenna array 222. In some examples, signals or signal patterns (before or after preparing) are phase shifted for each antenna of the antenna array 222 using the bidirectional phase shifter 218 with the DRL 220.

During signal reception operations, the device 202 operates to: receive reflected signals or signal patterns from the ambient environment 230 (e.g., due to the first object 232 and the second object 234) using the antenna array 222; phase shift the received signals or signal patterns using the transceiver 210; and analyze the phase shifted signals or signal patterns using the processor 204 to determine parameters of the first object 232 and/or the second object 234.

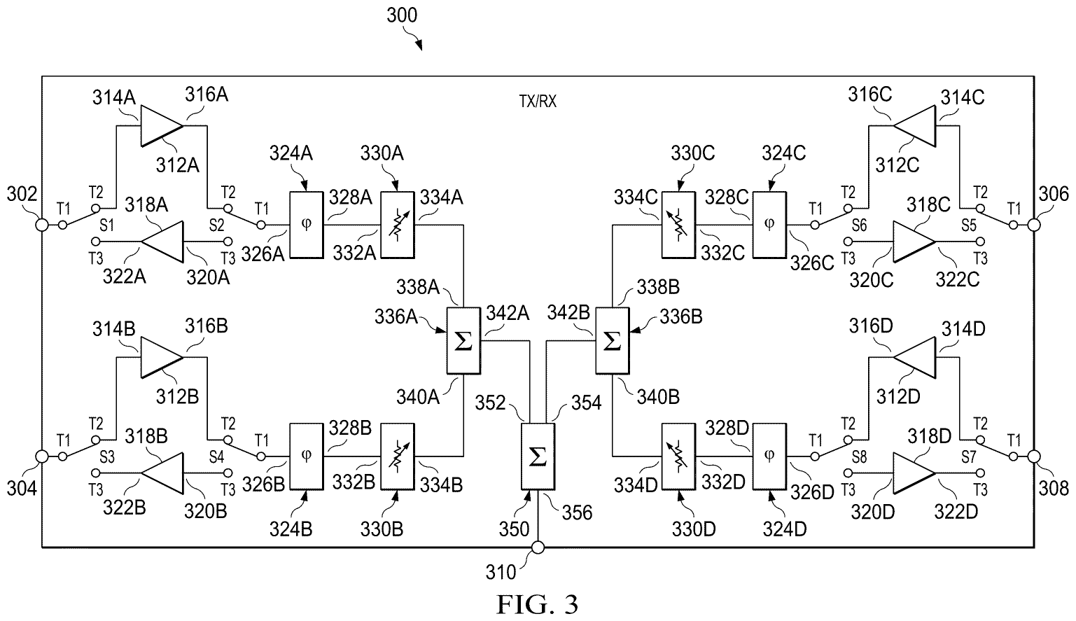

FIG. 3 is a diagram showing an example transceiver 300. The transceiver 300 is an example of the transceiver 110 in FIG. 1, the transceiver 140 in FIG. 1, or the transceiver 210 in FIG. 2. In the example of FIG. 3, the transceiver 300 has a first terminal 302, a second terminal 304, a third terminal 306, a fourth terminal 308, and a fifth terminal 310. The first terminal 302, the second terminal 304, the third terminal 306, and the fourth terminal 308 are examples of terminals of the third terminals 116A to 116N in FIG. 1, terminals of the third terminals 146A to 146N in FIG. 1, or terminals of the third terminals 216A to 216N in FIG. 2. The fifth terminal 310 is an example of a bidirectional terminal (a bidirectional terminal instead of the first terminal 112 and the second terminal 114 of the transceiver 110 in FIG. 1, a bidirectional terminal instead of the first terminal 142 and the second terminal 144 of the transceiver 140 in FIG. 1, or a bidirectional terminal instead of the first terminal 212 and the second terminal 214 of the transceiver 210 in FIG. 2.

In the example of FIG. 3, the transceiver 300 includes a switch S1, a first low-noise amplifier (LNA) 312A, a first power amplifier 318A, a switch S2, a first bidirectional phase shifter 324A, and first variable gain circuit 330A. The transceiver 300 also includes a switch S3, a second LNA 312B, a second power amplifier 318B, a switch S4, a second bidirectional phase shifter 324B, and second variable gain circuit 330B. The transceiver 300 also includes a switch S5, a third LNA 312C, a third power amplifier 318C, a switch S6, a third bidirectional phase shifter 324C, and third variable gain circuit 330C. The transceiver 300 also includes a switch S7, a fourth LNA 312D, a fourth power amplifier 318D, a switch S8, a fourth bidirectional phase shifter 324D, and fourth variable gain circuit 330D. The transceiver 300 also includes a first combiner/splitter circuit 336A, a second combiner/splitter circuit 336B, and a third combiner/splitter circuit 350.

The switch S1 has a first terminal T1, a second terminal T2, and a third terminal T3. The first LNA 312A has a first terminal 314A and a second terminal 316A. The first power amplifier 318A has a first terminal 320A and a second terminal 322A. The switch S2 has a first terminal T1, a second terminal T2, and a third terminal T3. The first bidirectional phase shifter 324A has a first terminal 326A and a second terminal 328A. The first variable gain circuit 330A has a first terminal 332A and a second terminal 334A.

The switch S3 has a first terminal T1, a second terminal T2, and a third terminal T3. The second LNA 312B has a first terminal 314B and a second terminal 316B. The second power amplifier 318B has a first terminal 320B and a second terminal 322B. The switch S4 has a first terminal T1, a second terminal T2, and a third terminal T3. The second bidirectional phase shifter 324B has a first terminal 326B and a second terminal 328B. The second variable gain circuit 330B has a first terminal 332B and a second terminal 334B.

The switch S5 has a first terminal T1, a second terminal T2, and a third terminal T3. The third LNA 312C has a first terminal 314C and a second terminal 316C. The third power amplifier 318C has a first terminal 320C and a second terminal 322C. The switch S6 has a first terminal T1, a second terminal T2, and a third terminal T3. The third bidirectional phase shifter 324C has a first terminal 326C and a second terminal 328C. The third variable gain circuit 330C has a first terminal 332C and a second terminal 334C.

The switch S7 has a first terminal T1, a second terminal T2, and a third terminal T3. The fourth LNA 312D has a first terminal 314D and a second terminal 316D. The fourth power amplifier 318C has a first terminal 320C and a second terminal 322C. The switch S8 has a first terminal T1, a second terminal T2, and a third terminal T3. The fourth bidirectional phase shifter 324D has a first terminal 326D and a second terminal 328D. The fourth variable gain circuit 330D has a first terminal 332D and a second terminal 334D.

The first combiner/splitter circuit 336A has a first terminal 338A, a second terminal 340A, and a third terminal 342A. The second combiner/splitter circuit 336B has a first terminal 338B, a second terminal 340B, and a third terminal 342B. The third combiner/splitter circuit 350 has a first terminal 352, a second terminal 354, and a third terminal 356.

The first terminal T1 of the switch S1 is coupled to the first terminal 302 of the transceiver 300. The second terminal T2 of the switch S1 is coupled to the first terminal 314A of the first LNA 312A. The second terminal 316A of the first LNA 312A is coupled to the second terminal T2 of the switch S2. The third terminal T3 of the switch S1 is coupled to the second terminal 322A of the first power amplifier 318A. The first terminal 320A of the first power amplifier 318A is coupled to the second terminal T2 of the switch S2. The first terminal T1 of the switch S2 is coupled to the first terminal 326A of the first bidirectional phase shifter 324A. The second terminal 328A of the first bidirectional phase shifter 324A is coupled to the first terminal 332A of the first variable gain circuit 330A. The second terminal 334A of the first variable gain circuit 330A is coupled to the first terminal 338A of the first combiner/splitter circuit 336A.

The first terminal T1 of the switch S3 is coupled to the second terminal 304 of the transceiver 300. The second terminal T2 of the switch S3 is coupled to the first terminal 314B of the second LNA 312B. The second terminal 316B of the second LNA 312B is coupled to the second terminal T2 of the switch S4. The third terminal T3 of the switch S3 is coupled to the second terminal 322B of the second power amplifier 318B. The first terminal 320B of the second power amplifier 318B is coupled to the second terminal T2 of the switch S4. The first terminal T1 of the switch S4 is coupled to the first terminal 326B of the second bidirectional phase shifter 324B. The second terminal 328B of the second bidirectional phase shifter 324B is coupled to the first terminal 332B of the second variable gain circuit 330B. The second terminal 334B of the second variable gain circuit 330B is coupled to the second terminal 340A of the first combiner/splitter circuit 336A.

The first terminal T1 of the switch S5 is coupled to the third terminal 306 of the transceiver 300. The second terminal T2 of the switch S5 is coupled to the first terminal 314C of the third LNA 312C. The second terminal 316C of the third LNA 312C is coupled to the second terminal T2 of the switch S6. The third terminal T3 of the switch S5 is coupled to the second terminal 322C of the third power amplifier 318C. The first terminal 320C of the third power amplifier 318C is coupled to the second terminal T2 of the switch S6. The first terminal T1 of the switch S6 is coupled to the first terminal 326C of the third bidirectional phase shifter 324C. The second terminal 328C of the third bidirectional phase shifter 324C is coupled to the first terminal 332C of the third variable gain circuit 330C. The second terminal 334C of the third variable gain circuit 330C is coupled to the first terminal 338B of the second combiner/splitter circuit 336B.

The first terminal T1 of the switch S7 is coupled to the fourth terminal 308 of the transceiver 300. The second terminal T2 of the switch S7 is coupled to the first terminal 314D of the fourth LNA 312D. The second terminal 316D of the fourth LNA 312D is coupled to the second terminal T2 of the switch S8. The third terminal T3 of the switch S7 is coupled to the second terminal 322D of the fourth power amplifier 318D. The first terminal 320D of the fourth power amplifier 318D is coupled to the second terminal T2 of the switch S8. The first terminal T1 of the switch S8 is coupled to the first terminal 326D of the fourth bidirectional phase shifter 324D. The second terminal 328D of the fourth bidirectional phase shifter 324D is coupled to the first terminal 332D of the fourth variable gain circuit 330D. The second terminal 334D of the fourth variable gain circuit 330D is coupled to the second terminal 340B of the second combiner/splitter circuit 336B. The third terminal 342A of the first combiner/splitter circuit 336A is coupled to the first terminal 352 of the third combiner/splitter circuit 350. The third terminal 342B of the second combiner/splitter circuit 336B is coupled to the second terminal 354 of the third combiner/splitter circuit 350. The third terminal 356 of the third combiner/splitter circuit 350 is coupled to the fifth terminal 310 of the transceiver 300.

In the example of FIG. 3, the first terminal 302, the second terminal 304, the third terminal 306, and the fourth terminal 308 may be referred to as antenna terminals. The fifth terminal 310 may be referred to as a processor terminal. In different examples, the number of antenna terminals and processor terminals of a transceiver may vary to support different numbers of antennas and processors.

In some examples, the transceiver 300 operates to receive or transmit signals from each of the first terminal 302, the second terminal 304, the third terminal 306, or the fourth terminal 308. To support receive and transmit operations, each of the switches S1 to S8 may have a respective control terminal (not shown) and may be controlled by a controller (not shown) for transmit operations or receive operations. When receiving a first signal at the first terminal 302, the switch S1 is set for receive operations and couples the first terminal 302 of the transceiver 300 to the first terminal 314A of the first LNA 312A. The first LNA 312A operates to: amplify the first signal received at the first terminal 314A based on low-noise amplification to obtain a first amplified signal; and provide the first amplified signal to the second terminal 316A. The first bidirectional phase shifter 324A operates to: receive the first amplified signal at the first terminal 326A via the switch S2, which is set for receive operations and couples the second terminal 316A of the first LNA 312A to the first terminal 326A of the first bidirectional phase shifter 324A; perform phase shifting of the first amplified signal to obtain a first phase-shifted signal; and provide the first phase-shifted signal at the second terminal 328A. The first variable gain circuit 330A operates to: receive the first phase-shifted signal at the first terminal 332A; apply a gain to the first phase-shifted signal to obtain a first adjusted signal; and provide the first adjusted signal at the second terminal 334A. In some examples, the gain applied by the first variable gain circuit 330A reverses amplitude changes introduced by the first bidirectional phase shifter 324A and/or normalizes the amplitude of the first adjusted signal relative to other received signals (e.g., signals received at the second terminal 304, the third terminal 306, and/or the fourth terminal 308). In some examples, the gain applied by the first variable gain circuit 330A is less than 1 (i.e., an attenuation is applied).

When receiving a second signal at the second terminal 304, the switch S3 is set for receive operations and couples the second terminal 304 of the transceiver 300 to the first terminal 314B of the second LNA 312B. The second LNA 312B operates to: amplify the second signal received at the first terminal 314B based on low-noise amplification to obtain a second amplified signal; and provide the second amplified signal to the second terminal 316B. The second bidirectional phase shifter 324B operates to: receive the second amplified signal at the first terminal 326B via the switch S4, which is set for receive operations and couples the second terminal 316B of the second LNA 312B to the first terminal 326B of the second bidirectional phase shifter 324B; perform phase shifting of the second amplified signal to obtain a second phase-shifted signal; and provide the second phase-shifted signal at the second terminal 328B. The second variable gain circuit 330B operates to: receive the second phase-shifted signal at the first terminal 332B; apply a gain to the second phase-shifted signal to obtain a second adjust signal; and provide the second adjusted signal at the second terminal 334B. In some examples, the gain applied by the second variable gain circuit 330B reverses amplitude changes introduced by the second bidirectional phase shifter 324B and/or normalizes the amplitude of the second adjusted signal relative to other received signals (e.g., signals received at the first terminal 302, the third terminal 306, and/or the fourth terminal 308). In some examples, the gain applied by the second variable gain circuit 330B is less than 1 (i.e., an attenuation is applied).

When receiving a third signal at the third terminal 306, the switch S5 is set for receive operations and couples the third terminal 306 of the transceiver 300 to the first terminal 314C of the third LNA 312C. The third LNA 312C operates to: amplify the third signal received at the first terminal 314C based on low-noise amplification to obtain a third amplified signal; and provide the third amplified signal to the second terminal 316C. The third bidirectional phase shifter 324C operates to: receive the third amplified signal at the first terminal 326C via the switch S6, which is set for receive operations and couples the second terminal 316C of the third LNA 312C to the first terminal 326C of the third bidirectional phase shifter 324C; perform phase shifting of the third amplified signal to obtain a third phase-shifted signal; and provide the third phase-shifted signal at the second terminal 328C. The third variable gain circuit 330C operates to: receive the third phase-shifted signal at the first terminal 332C; apply a gain to the third phase-shifted signal to obtain a third adjusted signal; and provide the third adjusted signal at the second terminal 334C. In some examples, the gain applied by the third variable gain circuit 330C reverses amplitude changes introduced by the third bidirectional phase shifter 324C and/or normalizes the amplitude of the third adjusted signal relative to other received signals (e.g., signals received at the first terminal 302, the second terminal 304, and/or the fourth terminal 308). In some examples, the gain applied by the third variable gain circuit 330C is less than 1 (i.e., an attenuation is applied).

When receiving a fourth signal at the fourth terminal 308, the switch S7 is set for receive operations and couples the fourth terminal 308 of the transceiver 300 to the first terminal 314D of the fourth LNA 312D. The fourth LNA 312D operates to: amplify the fourth signal received at the first terminal 314D based on low-noise amplification to obtain a fourth amplified signal; and provide the fourth amplified signal to the second terminal 316D. The fourth bidirectional phase shifter 324D operates to: receive the fourth amplified signal at the first terminal 326D via the switch S8, which is set for receive operations and couples the second terminal 316D of the fourth LNA 312D to the first terminal 326D of the fourth bidirectional phase shifter 324D; perform phase shifting of the fourth amplified signal to obtain a fourth phase-shifted signal; and provide the fourth phase-shifted signal at the second terminal 328D. The fourth variable gain circuit 330D operates to: receive the fourth phase-shifted signal at the first terminal 332D; apply a gain to the fourth phase-shifted signal to obtain a fourth adjusted signal; and provide the fourth adjusted signal at the second terminal 334D. In some examples, the gain applied by the fourth variable gain circuit 330D reverses amplitude changes introduced by the fourth bidirectional phase shifter 324D and/or normalizes the amplitude of the third adjusted signal relative to other received signals (e.g., signals received at the first terminal 302, the second terminal 304, and/or the third terminal 306). In some examples, the gain applied by the fourth variable gain circuit 330D is less than 1 (i.e., an attenuation is applied).

The first combiner/splitter circuit 336A operates to: receive the first adjusted signal at the first terminal 338A; receive the second adjusted signal at the second terminal 340A; and provide a first summation signal at the third terminal 342A responsive to the first and second adjusted signals. The second combiner/splitter circuit 336B operates to: receive the third adjusted signal at the first terminal 338B; receive the fourth adjusted signal at the second terminal 340B; and provide a second summation signal at the third terminal 342B responsive to the third and fourth adjusted signals. The third combiner/splitter circuit 350 operates to: receive the first summation signal at the first terminal 352; receive the second summation signal at the second terminal 354; and provide a third summation signal at the third terminal 356 responsive to the first and second summation signals. The third summation signal is provided to the fifth terminal 310 of the transceiver 300. In some examples, the third summation signal is provided to a processor for processing.

When transmitting, the transceiver 300 operates to: receive a base signal at the fifth terminal 310; split the base signal into branch signals using the third combiner/splitter circuit 350, the first combiner/splitter circuit 336A, and the second combiner/splitter circuit 336B; adjust the branch signals using the first, second, third, and fourth variable gain circuit 330A to 330D and the first, second, third, and fourth bidirectional phase shifters 324A to 324D. The

In some examples, the third combiner/splitter circuit 350 operates to: receive the base signal at the third terminal 356; provide a first split signal at the first terminal 352 responsive to the base signal and signal splitting operations of the third combiner/splitter circuit 350; and provide a second split signal at the second terminal 354 responsive to the base signal and signal splitting operations of the third combiner/splitter circuit 350.

In some examples, the first combiner/splitter circuit 336A operates to: receive the first split signal at the third terminal 342A; provide a first branch signal at the first terminal 338A responsive to the first split signal and signal splitting operations of the first combiner/splitter circuit 336A; and provide a second branch signal at the second terminal 340A responsive to the first split signal and signal splitting operations of the first combiner/splitter circuit 336A.

In some examples, the second combiner/splitter circuit 336B operates to: receive the second split signal at the third terminal 342B; provide a third branch signal at the first terminal 338B responsive to the second split signal and signal splitting operations of the second combiner/splitter circuit 336B; and provide a fourth branch signal at the second terminal 340B responsive to the second split signal and signal splitting operations of the second combiner/splitter circuit 336B.

The first bidirectional phase shifter 324A operates to: receive the first branch signal at the second terminal 328A; and provide a first phase-shifted branch signal at the first terminal 326A responsive to the first branch signal and phase-shift operations of the first bidirectional phase shifter 324A. The first power amplifier 318A operates to: receive the first phase-shifted branch signal at the first terminal 320A via the switch S2, which is set for transmit operations and couples the first terminal 326A of the first bidirectional phase shifter 324A to the first terminal 320A of the first power amplifier 318A; and provide a first amplified signal at the second terminal 322A responsive to the first phase-shifted branch signal and operations of the first power amplifier 318A. The first amplified signal is provided from the second terminal 322A of the first power amplifier 318A to the first terminal 302 of the transceiver 300 via the switch S1, which is set for transmit operations and couples the second terminal 322A of the first power amplifier 318A to the first terminal 302 of the transceiver 300.

The second bidirectional phase shifter 324B operates to: receive the second branch signal at the second terminal 328B; and provide a second phase-shifted branch signal at the first terminal 326B responsive to the second branch signal and phase-shift operations of the second bidirectional phase shifter 324B. The second power amplifier 318B operates to: receive the second phase-shifted branch signal at the first terminal 320B via the switch S4, which is set for transmit operations and couples the first terminal 326B of the second bidirectional phase shifter 324B to the first terminal 320B of the second power amplifier 318B; and provide a second amplified signal at the second terminal 322B responsive to the second phase-shifted branch signal and operations of the second power amplifier 318B. The second amplified signal is provided from the second terminal 322B of the second power amplifier 318B to the second terminal 304 of the transceiver 300 via the switch S3, which is set for transmit operations and couples the second terminal 322B of the second power amplifier 318B to the second terminal 304 of the transceiver 300.

The third bidirectional phase shifter 324C operates to: receive the third branch signal at the second terminal 328C; and provide a third phase-shifted branch signal at the first terminal 326C responsive to the third branch signal and phase-shift operations of the third bidirectional phase shifter 324C. The third power amplifier 318C operates to: receive the third phase-shifted branch signal at the first terminal 320C via the switch S6, which is set for transmit operations and couples the first terminal 326C of the third bidirectional phase shifter 324C to the first terminal 320C of the third power amplifier 318C; and provide a third amplified signal at the second terminal 322C responsive to the third phase-shifted branch signal and operations of the third power amplifier 318C. The third amplified signal is provided from the second terminal 322C of the third power amplifier 318C to the third terminal 306 of the transceiver 300 via the switch S5, which is set for transmit operations and couples the second terminal 322C of the third power amplifier 318C to the third terminal 306 of the transceiver 300.

The fourth bidirectional phase shifter 324D operates to: receive the fourth branch signal at the second terminal 328D; and provide a fourth phase-shifted branch signal at the first terminal 326D responsive to the fourth branch signal and phase-shift operations of the fourth bidirectional phase shifter 324D. The fourth power amplifier 318D operates to: receive the fourth phase-shifted branch signal at the first terminal 320D via the switch S8, which is set for transmit operations and couples the first terminal 326D of the fourth bidirectional phase shifter 324D to the first terminal 320D of the fourth power amplifier 318D; and provide a fourth amplified signal at the second terminal 322D responsive to the fourth phase-shifted branch signal and operations of the fourth power amplifier 318D. The fourth amplified signal is provided from the second terminal 322D of the fourth power amplifier 318D to the fourth terminal 308 of the transceiver 300 via the switch S7, which is set for transmit operations and couples the second terminal 322D of the fourth power amplifier 318D to the fourth terminal 308 of the transceiver 300.

In some examples, each of the first, second, third, and fourth bidirectional phase shifters 324A, 324B, 324C, and 324D include transmission lines with negative impedance cells to provide DRL functionality. Each transmission line may provide lowpass filtering or bandpass filtering. In some examples, each transmission line is a double-tuned transformer-based bandpass transmission line, which prevents crosstalk between the negative impedance cells. In some examples, the transmission lines provide passive functional or impedance matching for radio frequency/microwave applications (e.g., pass amplifier, filters, etc.).

In some examples, the transceiver 300 is an IC and each phase shifter (e.g., each of the first, second, third, and fourth bidirectional phase shifters 324A to 324D) includes a first transmission line with first negative impedance cells; a second transmission line with second negative impedance cells; and an I/Q generator having a first terminal, a second terminal, a third terminal, and a fourth terminal. The second terminal of the I/Q generator is coupled to the first transmission line. The third terminal of the I/Q generator is coupled to the second transmission line. In some examples, the transceiver 300 is used for radar or phased array communications (e.g., Satcom/5G) to control orthogonal phase and amplitude, which reduces calibration complexity for beam-steering and sidelobe suppression. In some examples, each phase shifter is a passive phase shifter supporting bidirectional operation, which simplifies beamformer architecture. In some examples, phase shifters are bidirectional “calibration-free” low-loss phase shifters with low RMS amplitude and low phase errors. In some examples, each phase shifter is based on true time delay options to support broadband operations. In some examples, each phase shifter operates at frequencies where switches cannot be designed. In some examples, each phase shifter include one or more of the following: a DRL; an active open switch circuit; and an active short switch circuit. In one example, a phase shifter is a bidirectional active RTPS with DRL. In some examples, DRL functionality is based on negative impedance cells, which enable embedded phase inversion. For example, such negative impedance cells may be switched between two states to support embedded phase inversion with flat amplitude response. In a first state A, a negative impedance cell may have a resistance

$${R}_{negA} = \frac{- {Z}_{0}}{1 + α} ,$$

where Z₀ is the characteristic impedance of the transmission line, and a is a generic value. In a second state B, a negative impedance cell may have a resistance

$${R}_{negB} = \frac{- α {Z}_{0}}{1 + α} .$$

The result of the two states is given as:

$${Γ}_{negA} = \frac{1 + α}{1 - α} and {Γ}_{negB} = \frac{1 + α}{α - 1} ,$$

where Γ_{negA} is the reflection coefficient of the first state A, Γ_{negB} is the reflection coefficient of the second state B. In some examples, Γ_{negA} and Γ_{negB} have same magnitude but are 180 degrees out of phase.

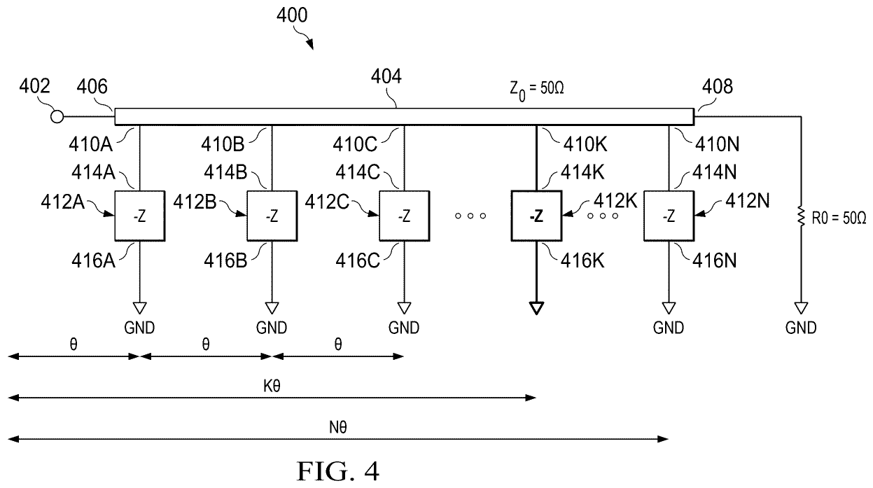

FIG. 4 is a diagram showing an example DRL 400 with negative impedance cells 412A to 412N. In the example of FIG. 4, the DRL 400 includes a terminal 402, an impedance line (signal path) 404, a resistor R0, and the negative impedance cells 412A to 412N. The impedance line 404 has a first terminal 406, a second terminal 408, and third terminals 410A to 410N. Each of the negative impedance cells 412A to 412N has a respective first terminal 414A to 414N and a respective second terminal 416A to 416N. The resistor R0 has a first terminal and a second terminal. In some examples, the impedance line 404 and the resistor R0 have matching resistances (e.g., 50Ω).

The terminal 402 of the DRL 400 is coupled to the first terminal 406 of the impedance line 404. The second terminal 408 of the impedance line 404 is coupled to the first terminal of the resistor R0. The second terminal of the resistor R0 is coupled to ground or a ground terminal. Each of the first terminals 414A to 414N of the negative impedance cells 412A to 412N is coupled to a respective terminal of the third terminals 410A to 410N of the impedance line 404. Each of the second terminals 416A to 416N of the negative impedance cells 412A to 412N is coupled to ground or a ground terminal.

In the example of FIG. 4, each of the negative impedance cells 412A to 412N provides a phase shift θ. In some examples, the negative impedance cells 412A to 412N are active open switch circuits or active short switches. In some examples, active open switches provide a phase shift of 0 or 360, while an active short switch provides a phase shift of 0 or 180. As desired, the amount of impedance of each negative impedance cells 412A to 412N can be varied (e.g., to match a particular impedance line).

With reflection, each phase shift is doubled relative to the terminal 402. For example, for a phase shift 2Kθ relative to the terminal 402, only the Kth negative impedance cell 412K is enabled. For a phase shift 2Nθ relative to the terminal 402, only the Nth negative impedance cell 412N is enabled. In some examples, the DRL 400 creates a phase-code independent “active open” to the right. In some examples, the DRL 400 is bidirectional due to each of the negative impedance cell 412A to 412N being a shunt negative impedance cell relative to the impedance line 404. In some examples, each of the negative impedance cell 412A to 412N compensates only the resistor R0 to reduce instability from parasitic series/shunt resonances. In the example of FIG. 4, the input voltage to the terminal 402 is an alternating-current (AC) voltage. In such examples, the positive voltage at the terminal 402 is V⁺=A∠0, the negative voltage at the terminal 402 is V⁻=A∠(0+2Kθ), and the total voltage at the terminal 402 is V=V⁺+V⁻, where A is the amplitude of the input voltage and ∠ is phase.

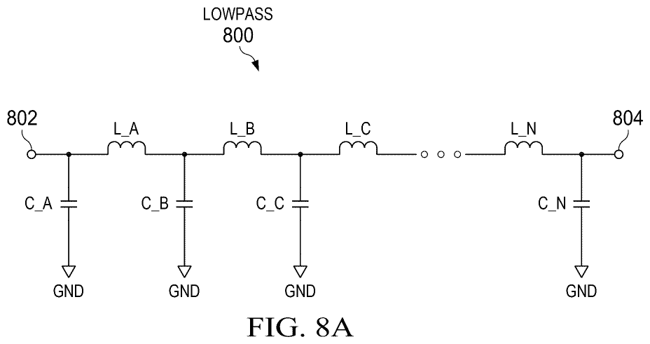

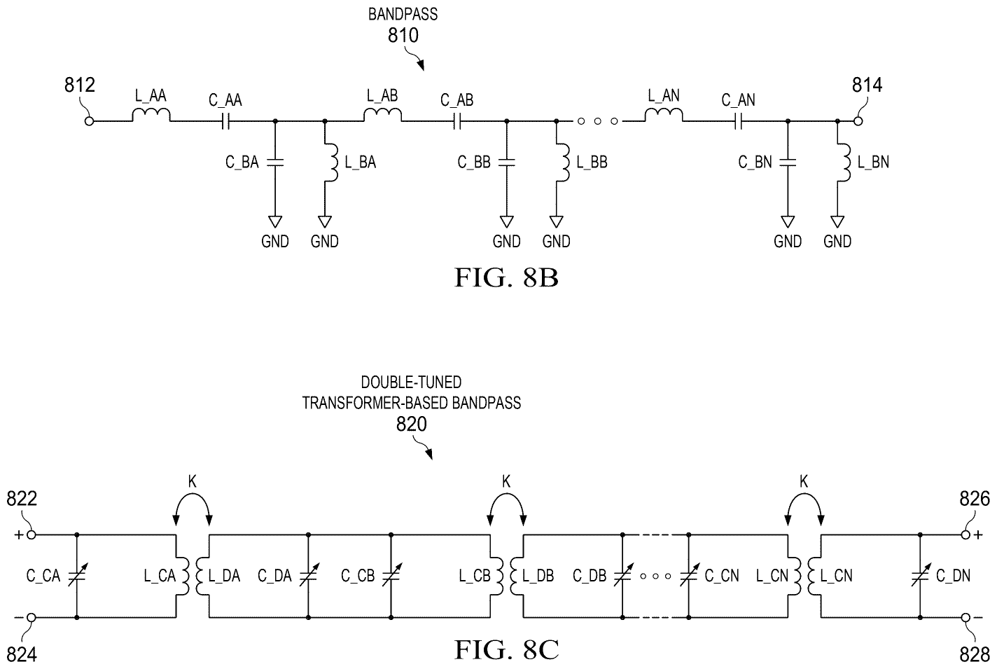

In the example of FIG. 4, the number of negative impedance cells (e.g., the negative impedance cells 412A to 412N) may vary to support different phase shift resolutions. In some examples, the number of negative impedance cells is limited by the length of the transmission line while maintaining the characteristic impedance (sqrt (L/C)). In some examples, a lambda/4 transmission line length is determined for a lowest target frequency of operation. This lambda/4 transmission line length defines a 180 degree phase shift based on round trip. The transmission line includes smaller units (e.g., capacitors, LC pairs, or double-tuned transformer-based bandpass units as in FIGS. 8A to 8C), where each unit includes a negative impedance cell. The smallest unit depends on the capacitive loading of the negative impedance cell. As the capacitance of the negative impedance cell increases, a higher inductance is needed to achieve a characteristic impedance (sqrt (L/C)) for the transmission line and fewer units are added. In some examples, a lambda/4 transmission line has 6 to 12 negative impedance cells.

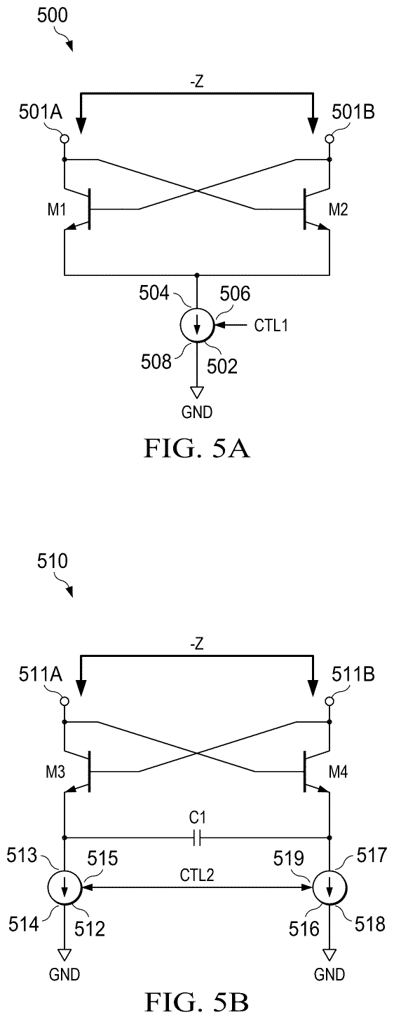

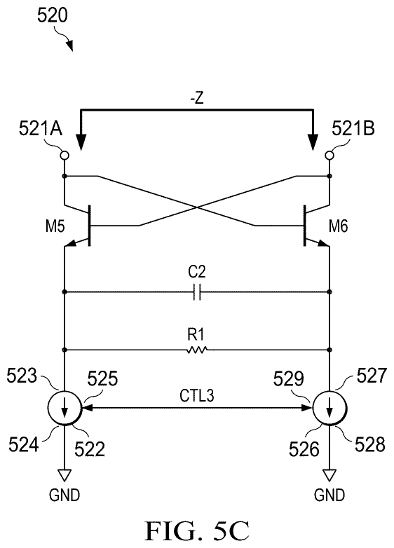

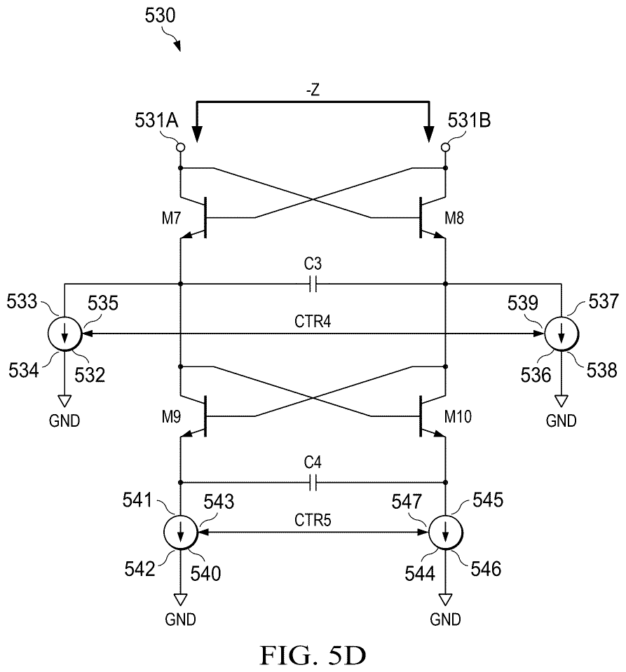

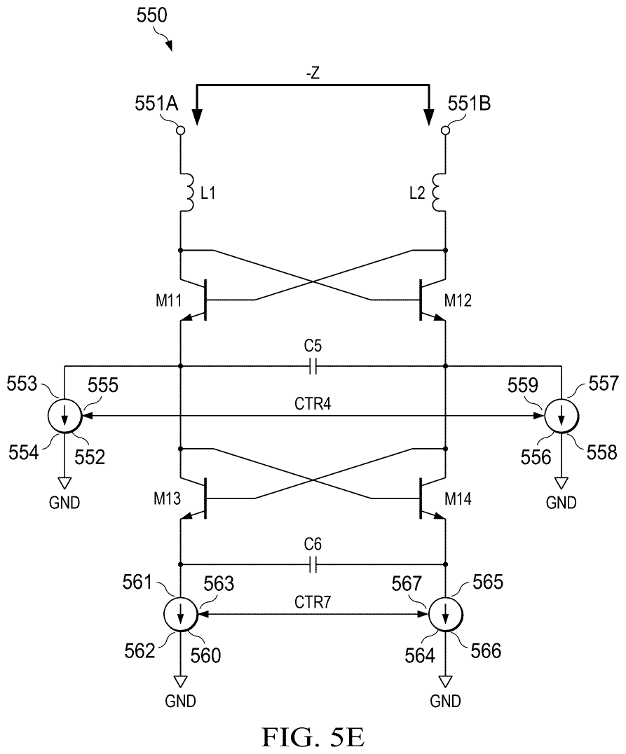

FIGS. 5A to 5E are schematic diagrams showing example negative impedance cells 500, 510, 520, 530, and 550. Each of the negative impedance cells 500, 510, 520, 530, and 550 are examples of active open switch circuits. The negative impedance cell 500 of FIG. 5A has a first terminal 501A and a second terminal 501B, where there is a negative impedance across the first terminal 501A and the second terminal 501B. For use in a DRL (e.g., the DRL 400 in FIG. 4), the first terminal 501A and the second terminal 501B are coupled to an impedance line (e.g., the impedance line 404 in FIG. 4).

The negative impedance cell 500 includes transistors M1 and M2, and a current source 502. In the example of FIG. 5A, the transistors M1 and M2 are NPN bipolar transistors. In other examples, metal-oxide semiconductor (MOS) transistors may be used. The transistor M1 has a first terminal, a second terminal, and a control terminal. The transistor M2 has a first terminal, a second terminal, and a control terminal. The current source 502 has a first terminal 504, a second terminal 506, and a third terminal 508.

The first terminal 501A of the negative impedance cell 500 is coupled to the first terminal of the transistor M1 and the control terminal of the transistor M2. The second terminal 501B of the negative impedance cell 500 is coupled to the first terminal of the transistor M2 and the control terminal of the transistor M1. The second terminals of the transistors M1 and M2 are coupled to the first terminal 504 of the current source 502. The second terminal 506 of the current source 502 is coupled to ground or a ground terminal. The third terminal 508 of the current source 502 receives a control signal CTL1 from a controller (not shown). The control signal CTL1 adjusts the current flow of the current source 502 responsive to a target impedance (e.g., 500, 1000, or other) for the negative impedance cell 500.

The negative impedance cell 510 of FIG. 5B has a first terminal 511A and a second terminal 511B, where there is a negative impedance across the first terminal 511A and the second terminal 511B. For use in a DRL (e.g., the DRL 400 in FIG. 4), the first terminal 511A and the second terminal 511B are coupled to an impedance line (e.g., the impedance line 404 in FIG. 4).

The negative impedance cell 510 includes transistors M3 and M4, a capacitor C1, a first current source 512, and a second current source 516. In the example of FIG. 5B, the transistors M3 and M4 are NPN bipolar transistors. In other examples, MOS transistors may be used.

The transistor M3 has a first terminal, a second terminal, and a control terminal. The transistor M4 has a first terminal, a second terminal, and a control terminal. The capacitor C1 has a first terminal and a second terminal. The first current source 512 has a first terminal 513, a second terminal 514, and a third terminal 515. The second current source 516 has a first terminal 517, a second terminal 518, and a third terminal 519.

The first terminal 511A of the negative impedance cell 510 is coupled to the first terminal of the transistor M3 and the control terminal of the transistor M4. The second terminal 511B of the negative impedance cell 510 is coupled to the first terminal of the transistor M4 and the control terminal of the transistor M3. The second terminal of the transistor M3 is coupled to the first terminal of the capacitor C1 and the first terminal 513 of the first current source 512. The second terminal 514 of the first current source 512 is coupled to ground or a ground terminal. The second terminal of the transistor M4 is coupled to the second terminal of the capacitor C1 and the first terminal 517 of the second current source 516. The second terminal 518 of the second current source 516 is coupled to ground or a ground terminal. The third terminal 515 of the first current source 512 and the third terminal 519 of the second current source 516 receive a control signal CTL2 from a controller (not shown). The control signal CTL2 adjusts the current flow of the first current source 512 and the second current source 516 responsive to a target impedance (e.g., 500, 1000, or other) for the negative impedance cell 510.

The negative impedance cell 520 of FIG. 5C has a first terminal 521A and a second terminal 521B, where there is a negative impedance across the first terminal 521A and the second terminal 521B. For use in a DRL (e.g., the DRL 400 in FIG. 4), the first terminal 521A and the second terminal 521B are coupled to an impedance line (e.g., the impedance line 404 in FIG. 4).

The negative impedance cell 520 includes transistors M5 and M6, a capacitor C2, a resistor R1, a first current source 522, and a second current source 526. In the example of FIG. 5C, the transistors M5 and M6 are NPN bipolar transistors. In other examples, MOS transistors may be used.

The transistor M5 has a first terminal, a second terminal, and a control terminal. The transistor M6 has a first terminal, a second terminal, and a control terminal. The capacitor C1 has a first terminal and a second terminal. The resistor R1 has a first terminal and a second terminal. The first current source 522 has a first terminal 523, a second terminal 524, and a third terminal 525. The second current source 526 has a first terminal 527, a second terminal 528, and a third terminal 529.

The first terminal 521A of the negative impedance cell 520 is coupled to the first terminal of the transistor M5 and the control terminal of the transistor M6. The second terminal 521B of the negative impedance cell 520 is coupled to the first terminal of the transistor M6 and the control terminal of the transistor M5. The second terminal of the transistor M5 is coupled to the first terminal of the capacitor C2, the first terminal of the resistor R1, and the first terminal 523 of the first current source 522. The second terminal 524 of the first current source 522 is coupled to ground or a ground terminal. The second terminal of the transistor M6 is coupled to the second terminal of the capacitor C2, the second terminal of the resistor R1, and the first terminal 527 of the second current source 526. The second terminal 528 of the second current source 526 is coupled to ground or a ground terminal. The third terminal 525 of the first current source 522 and the third terminal 529 of the second current source 526 receive a control signal CTL3 from a controller (not shown). The control signal CTL3 adjusts the current flow of the first current source 522 and the second current source 526 responsive to a target impedance (e.g., 500, 1000, or other) for the negative impedance cell 520.

The negative impedance cell 530 of FIG. 5D has a first terminal 531A and a second terminal 531B, where there is a negative impedance across the first terminal 531A and the second terminal 531B. For use in a DRL (e.g., the DRL 400 in FIG. 4), the first terminal 531A and the second terminal 531B are coupled to an impedance line (e.g., the impedance line 404 in FIG. 4).

The negative impedance cell 530 includes transistors M7 to M10, a capacitor C3, a capacitor C4, a first current source 532, a second current source 536, a third current source 540, and a fourth current source 544. In the example of FIG. 5D, the transistors M7 to M10 are NPN bipolar transistors. In other examples, MOS transistors may be used.

Each of the transistors M7 to M10 has a respective first terminal, a respective second terminal, and a respective control terminal. The capacitor C3 has a first terminal and a second terminal. The capacitor C4 has a first terminal and a second terminal. The first current source 532 has a first terminal 533, a second terminal 534, and a third terminal 535. The second current source 536 has a first terminal 537, a second terminal 538, and a third terminal 539. The third current source 540 has a first terminal 541, a second terminal 542, and a third terminal 543. The fourth current source 544 has a first terminal 545, a second terminal 546, and a third terminal 547.

The first terminal 531A of the negative impedance cell 530 is coupled to the first terminal of the transistor M7 and the control terminal of the transistor M8. The second terminal 531B of the negative impedance cell 530 is coupled to the first terminal of the transistor M8 and the control terminal of the transistor M7. The second terminal of the transistor M7 is coupled to the first terminal of the capacitor C3 and the first terminal 533 of the first current source 532. The second terminal 534 of the first current source 532 is coupled to ground or a ground terminal. The second terminal of the transistor M8 is coupled to the second terminal of the capacitor C3 and the first terminal 537 of the second current source 536. The second terminal 538 of the second current source 536 is coupled to ground or a ground terminal. The third terminal 535 of the first current source 532 and the third terminal 539 of the second current source 536 receive a control signal CTL4 from a controller (not shown). The control signal CTL4 adjusts the current flow of the first current source 532 and the second current source 536 responsive to a target impedance (e.g., 500, 1000, or other) for the negative impedance cell 530.

As shown, the second terminal of the transistor M7 is also coupled to the first terminal of the transistor M9 and the control terminal of the transistor M10. The second terminal of the transistor M8 is also coupled to the first terminal of the transistor M10 and the control terminal of the transistor M9. The second terminal of the transistor M9 is coupled to the first terminal of the capacitor C4 and the first terminal 541 of the third current source 540. The second terminal 542 of the third current source 540 is coupled to ground or a ground terminal. The second terminal of the transistor M10 is coupled to the second terminal of the capacitor C4 and the first terminal 545 of the fourth current source 544. The second terminal 546 of the fourth current source 544 is coupled to ground or a ground terminal. The third terminal 543 of the third current source 540 and the third terminal 547 of the fourth current source 544 receive a control signal CTL5 from a controller (not shown). The control signal CTL5 adjusts the current flow of the third current source 540 and the fourth current source 544 responsive to a target impedance (e.g., 500, 1000, or other) for the negative impedance cell 530.

The negative impedance cell 550 of FIG. 5E has a first terminal 551A and a second terminal 551B, where there is a negative impedance across the first terminal 551A and the second terminal 551B. For use in a DRL (e.g., the DRL 400 in FIG. 4), the first terminal 551A and the second terminal 551B are coupled to an impedance line (e.g., the impedance line 404 in FIG. 4).

The negative impedance cell 550 includes transistors M11 to M14, inductors L1 and L2, capacitors C5 and C6, a first current source 552, a second current source 556, a third current source 560, and a fourth current source 564. In the example of FIG. 5E, the transistors M11 to M14 are NPN bipolar transistors. In other examples, MOS transistors may be used.

Each of the transistor M11 to M14 has a respective first terminal, a respective second terminal, and a respective control terminal. The capacitor C5 has a first terminal and a second terminal. The capacitor C6 has a first terminal and a second terminal. The first current source 552 has a first terminal 553, a second terminal 554, and a third terminal 555. The second current source 556 has a first terminal 557, a second terminal 558, and a third terminal 559. The third current source 560 has a first terminal 561, a second terminal 562, and a third terminal 563. The fourth current source 564 has a first terminal 565, a second terminal 566, and a third terminal 567.

The first terminal 551A of the negative impedance cell 550 is coupled to the first terminal of the inductor L1. The second terminal of the inductor L1 is coupled to the first terminal of the transistor M11 and the control terminal of the transistor M12. The second terminal 551B of the negative impedance cell 550 is coupled to the first terminal of the inductor L2. The second terminal of the inductor L2 is coupled to the first terminal of the transistor M12 and the control terminal of the transistor M11. The second terminal of the transistor M11 is coupled to the first terminal of the capacitor C5 and the first terminal 553 of the first current source 552. The second terminal 554 of the first current source 552 is coupled to ground or a ground terminal. The second terminal of the transistor M12 is coupled to the second terminal of the capacitor C5 and the first terminal 557 of the second current source 556. The second terminal 558 of the second current source 556 is coupled to ground or a ground terminal. The second terminal 558 of the second current source 556 is coupled to ground or a ground terminal. The third terminal 555 of the first current source 552 and the third terminal 559 of the second current source 556 receive a control signal CTL4 from a controller (not shown). The control signal CTL4 adjusts the current flow of the first current source 552 and the second current source 556 responsive to a target impedance (e.g., 500, 1000, or other) for the negative impedance cell 550.

As shown, the second terminal of the transistor M11 is also coupled to the first terminal of the transistor M13 and the control terminal of the transistor M14. The second terminal of the transistor M12 is also coupled to the first terminal of the transistor M14 and the control terminal of the transistor M13. The second terminal of the transistor M13 is coupled to the first terminal of the capacitor C6 and the first terminal 561 of the third current source 560. The second terminal 562 of the third current source 560 is coupled to ground or a ground terminal. The second terminal of the transistor M14 is coupled to the second terminal of the capacitor C6 and the first terminal 565 of the fourth current source 564. The second terminal 566 of the fourth current source 564 is coupled to ground or a ground terminal. The third terminal 563 of the third current source 560 and the third terminal 567 of the fourth current source 564 receive a control signal CTL6 from a controller (not shown). The control signal CTL6 adjusts the current flow of the third current source 560 and the fourth current source 564 responsive to a target impedance (e.g., 500, 1000, or other) for the negative impedance cell 550.

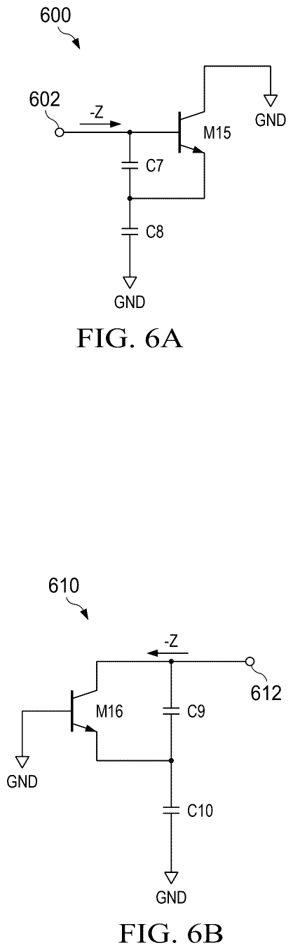

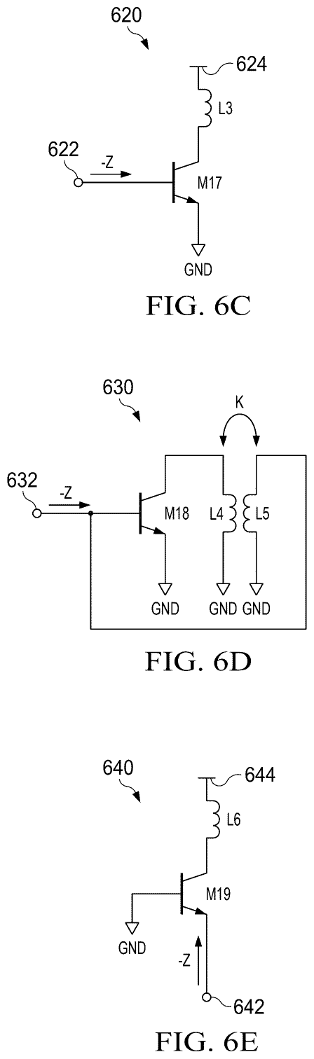

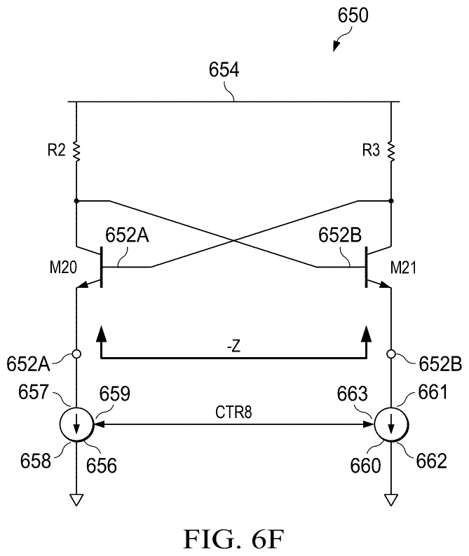

FIGS. 6A to 6F are schematic diagrams showing other example negative impedance cells 600, 610, 620. 630, 640, and 650. The negative impedance cells 600, 610, 620. 630, 640, and 650 are examples of active open switch circuits. The negative impedance cell 600 of FIG. 6A has a terminal 602, where there is a negative impedance at the terminal 602. For use in a DRL (e.g., the DRL 400 in FIG. 4), the terminal 602 is coupled to an impedance line (e.g., the impedance line 404 in FIG. 4).

The negative impedance cell 600 includes a transistor M15, a capacitor C7, and a capacitor C8. The transistor M15 has a first terminal, a second terminal, and a control terminal. The capacitor C7 has a first terminal and a second terminal. The capacitor C8 has a first terminal and a second terminal. In the example of FIG. 6A, the transistor M15 is an NPN bipolar transistor. In other examples, a MOS transistor may be used.

As shown, the terminal 602 is coupled to the first terminal of the capacitor C7 and the control terminal of the transistor M15. The first terminal of the transistor M15 is coupled to ground or a ground terminal. The second terminal of the capacitor C7 is coupled to the second terminal of the transistor M15 and the first terminal of the capacitor C8. The second terminal of the capacitor C8 is coupled to ground or a ground terminal.

The negative impedance cell 610 of FIG. 6B has a terminal 612, where there is a negative impedance at the terminal 612. For use in a DRL (e.g., the DRL 400 in FIG. 4), the terminal 612 is coupled to an impedance line (e.g., the impedance line 404 in FIG. 4).

The negative impedance cell 610 includes a transistor M16, a capacitor C9, and a capacitor C10. The transistor M16 has a first terminal, a second terminal, and a control terminal. The capacitor C9 has a first terminal and a second terminal. The capacitor C10 has a first terminal and a second terminal. In the example of FIG. 6B, the transistor M16 is an NPN bipolar transistor. In other examples, a MOS transistor may be used.

As shown, the terminal 612 is coupled to the first terminal of the capacitor C9 and the first terminal of the transistor M16. The control terminal of the transistor M16 is coupled to ground or a ground terminal. The second terminal of the transistor M16 is coupled to the second terminal of the capacitor C9 and the first terminal of the capacitor C10. The second terminal of the capacitor C10 is coupled to ground or a ground terminal.

The negative impedance cell 620 of FIG. 6C has a first terminal 622 and a second terminal 624, where there is a negative impedance at the first terminal 622. For use in a DRL (e.g., the DRL 400 in FIG. 4), the first terminal 622 is coupled to an impedance line (e.g., the impedance line 404 in FIG. 4).

The negative impedance cell 620 includes a transistor M17 and an inductor L3. The transistor M17 has a first terminal, a second terminal, and a control terminal. The inductor L3 has a first terminal and a second terminal. In the example of FIG. 6C, the transistor M17 is an NPN bipolar transistor. In other examples, a MOS transistor may be used.

As shown, the first terminal of the inductor L3 is coupled to the second terminal 624, which is a power supply terminal in the example of FIG. 6C. The second terminal of the inductor L3 is coupled to the first terminal of the transistor M17. The control terminal of the transistor M17 is coupled to the first terminal 622. The second terminal of the transistor M17 is coupled to ground or a ground terminal.

The negative impedance cell 630 of FIG. 6D has a terminal 632, where there is a negative impedance at the terminal 632. For use in a DRL (e.g., the DRL 400 in FIG. 4), the terminal 632 is coupled to an impedance line (e.g., the impedance line 404 in FIG. 4).

The negative impedance cell 630 includes a transistor M18, a first inductor L4, and a second inductor L5. In some examples, the inductors L4 and L5 operate as a transformer with a coupling factor K. The transistor M18 has a first terminal, a second terminal, and a control terminal. The inductor L4 has a first terminal and a second terminal. The inductor L5 has a first terminal and a second terminal. In the example of FIG. 6D, the transistor M18 is an NPN bipolar transistor. In other examples, a MOS transistor may be used.

As shown, the terminal 632 is coupled to the control terminal of the transistor M18 and the first terminal of the inductor L5. The first terminal of the transistor M18 is coupled to the first terminal of the inductor L4. The second terminals of the transistor M18, the inductor L4, and the inductor L5 are coupled to ground or ground terminals.

The negative impedance cell 640 of FIG. 6E has a first terminal 642 and a second terminal 644, where there is a negative impedance at the first terminal 642. For use in a DRL (e.g., the DRL 400 in FIG. 4), the first terminal 642 is coupled to an impedance line (e.g., the impedance line 404 in FIG. 4).

The negative impedance cell 640 includes a transistor M19 and an inductor L6. The transistor M19 has a first terminal, a second terminal, and a control terminal. The inductor L6 has a first terminal and a second terminal. In the example of FIG. 6E, the transistor M19 is an NPN bipolar transistor. In other examples, a MOS transistor may be used.

As shown, the first terminal of the inductor L6 is coupled to the second terminal 624, which is a power supply terminal in the example of FIG. 6E. The second terminal of the inductor L6 is coupled to the first terminal of the transistor M19. The control terminal of the transistor M19 is coupled to ground or a ground terminal. The second terminal of the transistor M19 is coupled to the first terminal 642.

The negative impedance cell 650 of FIG. 6F has a first terminal 652A, a second terminal 652B, and a third terminal 654, where there is a negative impedance across the first terminal 652A and the second terminal 652B. For use in a DRL (e.g., the DRL 400 in FIG. 4), the first terminal 652A and the second terminal 652B are coupled to an impedance line (e.g., the impedance line 404 in FIG. 4).

The negative impedance cell 650 includes transistors M20 and M21, a resistor R2, resistor R3, a first current source 656, and a second current source 660. In the example of FIG. 6F, the transistors M20 and M21 are NPN bipolar transistors. In other examples, MOS transistors may be used.

The transistor M20 has a first terminal, a second terminal, and a control terminal. The transistor M21 has a first terminal, a second terminal, and a control terminal. The resistor R2 has a first terminal and a second terminal. The resistor R3 has a first terminal and a second terminal. The first current source 656 has a first terminal 657, a second terminal 658, and a third terminal 659. The second current source 660 has a first terminal 661, a second terminal 662, and a third terminal 663.

The first terminal 652A of the negative impedance cell 650 is coupled to the second terminal of the transistor M20 and the first terminal 657 of the first current source 656. The second terminal 658 of the first current source 656 is coupled to ground or a ground terminal. The second terminal 652B of the negative impedance cell 650 is coupled to the second terminal of the transistor M21 and the first terminal 661 of the second current source 660. The second terminal 662 of the second current source 660 is coupled to ground or a ground terminal. The first terminal of the transistor M20 is coupled to the control terminal of the transistor M21 and the second terminal of the resistor R2. The first terminal of the resistor R2 is coupled to the third terminal 654, which is a power supply terminal in the example of FIG. 6F. The first terminal of the transistor M21 is coupled to the control terminal of the transistor M20 and the second terminal of the of the resistor R3. The first terminal of the resistor R3 is coupled to the third terminal 654. The third terminal 659 of the first current source 656 and the third terminal 663 of the second current source 660 receive a control signal CTL8 from a controller (not shown). The control signal CTL8 adjusts the current flow of the first current source 656 and the second current source 660 responsive to a target impedance (e.g., 500, 100Ω, or other) for the negative impedance cell 650.

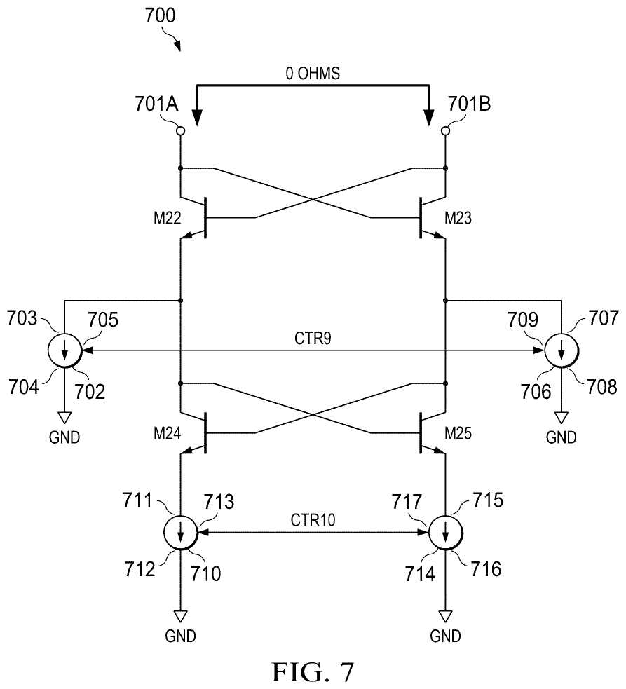

FIG. 7 is a schematic diagram showing another example negative impedance cell 700. The negative impedance cell 700 is an active short switch circuit. The negative impedance cell 700 has a first terminal 701A and a second terminal 701B, where there is a short (i.e., 0Ω) across the first terminal 701A and the second terminal 701B. For use in a DRL (e.g., the DRL 400 in FIG. 4), the first terminal 701A and the second terminal 701B are coupled to an impedance line (e.g., the impedance line 404 in FIG. 4).

The negative impedance cell 700 includes transistors M22 to M25, a first current source 702, a second current source 706, a third current source 710, and a fourth current source 714. In the example of FIG. 7, the transistors M22 to M25 are NPN bipolar transistors. In other examples, MOS transistors may be used.

Each of the transistors M22 to M25 has a respective first terminal, a respective second terminal, and a respective control terminal. The first current source 702 has a first terminal 703, a second terminal 704, and a third terminal 705. The second current source 706 has a first terminal 707, a second terminal 708, and a third terminal 709. The third current source 710 has a first terminal 711, a second terminal 712, and a third terminal 713. The fourth current source 714 has a first terminal 715, a second terminal 716, and a third terminal 717.

The first terminal 701A of the negative impedance cell 700 is coupled to the first terminal of the transistor M22 and the control terminal of the transistor M23. The second terminal 701B of the negative impedance cell 700 is coupled to the first terminal of the transistor M23 and the control terminal of the transistor M22. The second terminal of the transistor M22 is coupled to the first terminal 703 of the first current source 702. The second terminal 704 of the first current source 702 is coupled to ground or a ground terminal. The second terminal of the transistor M23 is coupled to the first terminal 707 of the second current source 706. The second terminal 708 of the second current source 706 is coupled to ground or a ground terminal. The third terminal 705 of the first current source 702 and the third terminal 709 of the second current source 706 receive a control signal CTL9 from a controller (not shown). The control signal CTL9 adjusts the current flow of the first current source 702 and the second current source 706 responsive to a target impedance (e.g., 500, 1000, or other) for the negative impedance cell 700.

As shown, the second terminal of the transistor M22 is also coupled to the first terminal of the transistor M24 and the control terminal of the transistor M25. The second terminal of the transistor M23 is also coupled to the first terminal of the transistor M25 and the control terminal of the transistor M24. The second terminal of the transistor M24 is coupled to the first terminal 711 of the third current source 710. The second terminal 712 of the third current source 710 is coupled to ground or a ground terminal. The second terminal of the transistor M25 is coupled to the first terminal 715 of the fourth current source 714. The second terminal 716 of the fourth current source 714 is coupled to ground or a ground terminal. The third terminal 713 of the third current source 710 and the third terminal 717 of the fourth current source 714 receive a control signal CTL10 from a controller (not shown). The control signal CTL10 adjusts the current flow of the third current source 710 and the fourth current source 714 responsive to a target impedance (e.g., 500, 100Ω, or other) for the negative impedance cell 700.

FIGS. 8A to 8C are schematic diagrams showing example transmission lines 800, 810, 820. The transmission line 800 is a lowpass transmission line. As shown, the transmission line 800 has a first terminal 802 and a second terminal 804. The transmission line 800 includes inductors L_A to L_N and capacitors C_A to C_N. Each of the inductors L_A to L_N has a respective first terminal and a respective second terminal. Each of the capacitors C_A to C_N has a respective first terminal and a respective second terminal.

In the example of FIG. 8A, the inductors L_A to L_N are in series between the first terminal 802 and the second terminal 804. Specifically, the first terminal of the inductor L_A is coupled to first terminal 802. The second terminal of the inductor L_A is coupled to the first terminal of the inductor L_B, the second terminal of the inductor L_B is coupled to the first terminal of the inductor L_C, and so on. The first terminal of the capacitor C_A is coupled to the first terminal 802 and the first terminal of the inductor L_A, the first terminal of the capacitor C_B is coupled to the second terminal of the inductor L_A and the first terminal of the inductor L_B, and so on. The second terminals of the capacitors C_A to C_N are coupled to ground or ground terminals. In some examples, a negative impedance cell (e.g., one of the negative impedance cells in FIGS. 5A to 5E, 6A to 6F, and 7) is added in parallel with each respective capacitor of the capacitors C_A to C_N to provide DRL functionality.

The transmission line 810 of FIG. 8B is a bandpass transmission line. As shown, the transmission line 810 has a first terminal 812 and a second terminal 814. The transmission line 810 includes inductors L_AA to L_AN and L_BA to L_BN and has capacitors C_AA to C_AN to C_BA to C_BN. Each of the inductors L_AA to L_AN and L_BA to L_BN has a respective first terminal and a respective second terminal. Each of the capacitors C_AA to C_AN to C_BA to C_BN has a respective first terminal and a respective second terminal.

In the example of FIG. 8B, the inductors L_AA to L_AN and the capacitors C_AA to C_AN are paired as series LC pairs and are coupled between the first terminal 812 and the second terminal 814. Specifically, the inductor L_AA and the capacitor C_AA are a series LC pair, the inductor L_AB and the capacitor C_AB are a series LC pair, and so on. As shown, the inductors L_BA to L_BN and the capacitors C_BA to C_NN are paired as parallel LC pairs and coupled in parallel between the series LC pairs. For example, the parallel LC pair C_BA and L_BA are coupled between the series LC pair L_AA and C_AA and the series LC pair L_AB and C_AB, the parallel LC pair C_BB and L_BB are coupled between the series LC pair L_AB and C_AB and a next series LC pair (e.g., L_AC and C_AC), and so on. In some examples, a negative impedance cell (e.g., one of the negative impedance cells in FIGS. 5A to 5E, 6A to 6F, and 7) is added in parallel with each respective LC pair to provide DRL functionality.

The transmission line 820 of FIG. 80 is a double-tuned transformer-based bandpass transmission line. As shown, the transmission line 820 has a first terminal 822, a second terminal 824, a third terminal 826, and a fourth terminal 828. The transmission line 820 includes varactors C_CA to C_CN, varactors C_DA to C_DN, inductors L_CA to L_CN and L_DA to L_DN. Each of the varactors C_CA to C_CN and varactors C_DA to C_DN has a respective first terminal and a respective second terminal. Each of the inductors L_CA to L_CN and L_DA to L_DN has a respective first terminal and a respective second terminal.

In the example of FIG. 8C, the varactors C_CA to C_CN, varactors C_DA to C_DN and the inductors L_CA to L_CN and L_DA to L_DN are grouped into double-tuned transformer-based bandpass units (sometimes referred to herein as just “bandpass units”). For the example, the varactor C_CA, the inductor L_CA, the inductor L_DA, and the varactor C_DA are a double-tuned transformer-based bandpass unit, where the inductors L_CA and L_DA form a transformer with a coupling factor K. Also, the varactor C_CB, the inductor L_CB, the inductor L_DB, and the varactor C_DB are a double-tuned transformer-based bandpass unit, where the inductors L_CB and L_DB form a transformer with a coupling factor K, and so on.

As shown, the first terminal 822 of the transmission line 820 is coupled to the first terminals of the varactor C_CA and the inductor L_CA. The second terminal 824 of the transmission line 820 is coupled to the second terminals of the varactor C_CA and the inductor L_CA. The first terminals of the inductor L_DA, the varactor C_DA, the varactor C_CB, and the inductor L_CB are coupled together. Also, the second terminals of the inductor L_DA, the varactor C_DA, the varactor C_CB, and the inductor L_CB are coupled together, and so on.

With each double-tuned transformer-based bandpass unit, the bandpass frequencies are set by the inductor and capacitors values. Insertion loss is set by transformer k-factor and Q values. Also, each double-tuned transformer-based bandpass unit is crosstalk immune due to fields being confined in the proximity of each transformer. In some examples, a negative impedance cell (e.g., one of the negative impedance cells in FIGS. 5A to 5E, 6A to 6F, and 7) is added in parallel with each respective varactor to provide DRL functionality.

A double-tuned transformer-based bandpass transmission line, such as the transmission line 820, provides various advantages compared to CL-LC bandpass transmission lines. Example advantages include: being more compact due to use of vertically stacked inductors for each transformer; broadband tuned behavior; no crosstalk between double-tuned transformer-based bandpass units; improved capacitance absorption compared to lowpass transmission lines; easy differential and single-ended implementation; operating each transformer as a balun to enable differential to single-ended conversion; a simplified bias through center tap of each transformer; easy implementation at mm-Wave frequencies; and easy impedance transformation at the source and load side through the transformer.

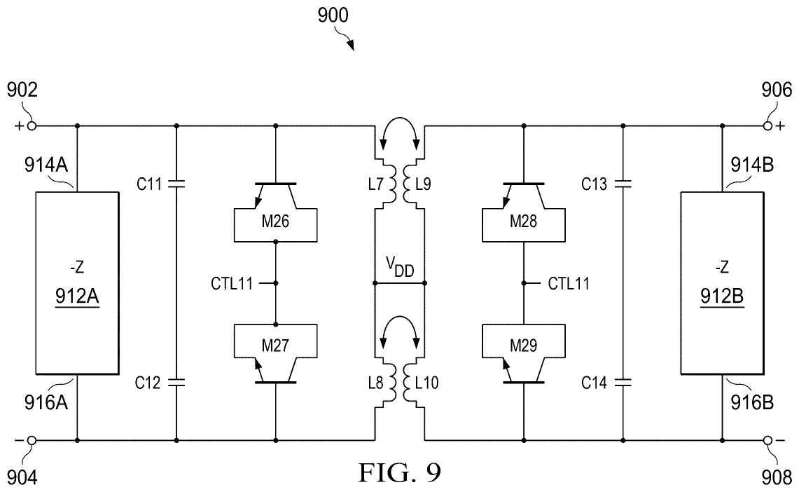

FIG. 9 is a diagram showing a double-tuned transformer-based bandpass unit 900. The double-tuned transformer-based bandpass unit 900 is an alternative to each double-tuned transformer-based bandpass unit in FIG. 8C (e.g., the bandpass unit with the varactor C_CA, the inductor L_CA, the inductor L_DA, and the varactor C_DA, and so on). As shown, the double-tuned transformer-based bandpass unit 900 has a first terminal 902, a second terminal 904, and third terminal 906, and a fourth terminal 908. In the example of FIG. 9, the double-tuned transformer-based bandpass unit 900 includes a first negative impedance cell 912A, a second negative impedance cell 912B, capacitors C11 to C14, transistor M26 to M29, and inductors L7 to L10. The first negative impedance cell 912A has a first terminal 914A and a second terminal 916A. The second negative impedance cell 912B has a first terminal 914B and a second terminal 916B. In some examples, the first negative impedance cell 912A is an active open circuit as in FIGS. 5A to 5E, 6A to 6F. In other examples, the first negative impedance cell 912A is an active short circuit as in FIG. 7). In some examples, the second negative impedance cell 912B is an active open circuit as in FIGS. 5A to 5E, 6A to 6F. In other examples, the second negative impedance cell 912B is an active short circuit as in FIG. 7. While not required, the first and second negative impedance cells 912A and 912B may have the same topology.

Each of the capacitors C11 to C14 has a respective first terminal and a respective second terminal. Each of the transistor M26 to M29 has a respective first terminal, a respective second terminal, and a respective control terminal. Each of the inductors L7 to L10 has a first terminal and a second terminal. The inductors L7 and L9 form a first transformer. The inductors L8 and L10 form a second transformer. In the example of FIG. 9, the transistors M26 to M29 are NPN bipolar transistors. In other examples, MOS transistors may be used.

As shown, the first terminal 902 of the double-tuned transformer-based bandpass unit 900 is coupled to the first terminal 914A of the first negative impedance cell 912A, the first terminal of the capacitor C11, the control terminal of the transistor M26, and the first terminal of the inductor L7. The second terminal of the capacitor C11 is coupled to the first terminal of the capacitor C12. The first and second terminals of the transistor M26 are coupled to the each other and to the first and second terminals of the transistor M27. The second terminal of the inductor L7 and the first terminal of the inductor L8 are coupled to a power supply (VDD) or related terminal. The second terminal 916A of the first negative impedance cell 912A is coupled to the second terminal 904 of the double-tuned transformer-based bandpass unit 900, the second terminal of the capacitor C12, the control terminal of the transistor M27, and the second terminal of the inductor L8.

The third terminal 906 of the double-tuned transformer-based bandpass unit 900 is coupled to the first terminal 914B of the second negative impedance cell 912B, the first terminal of the capacitor C13, the control terminal of the transistor M28, and the first terminal of the inductor L9. The second terminal of the capacitor C13 is coupled to the first terminal of the capacitor C14. The first and second terminals of the transistor M28 are coupled to the each other and to the first and second terminals of the transistor M29. The second terminal of the inductor L9 and the first terminal of the inductor L10 are coupled to a power supply (VDD) or related terminal. The second terminal 916B of the second negative impedance cell 912B is coupled to the fourth terminal 908 of the double-tuned transformer-based bandpass unit 900, the second terminal of the capacitor C14, the control terminal of the transistor M29, and the second terminal of the inductor L8.

In the example of FIG. 9, the capacitance between the first terminal 902 and the second terminal 904 is a function of the capacitors C11 and C12, and the transistors M26 and M27. To adjust the effective capacitance (e.g., to implement a varactor as in FIG. 8C) between the first terminal 902 and the second terminal 904, a control signal CTL11 is applied to the first and second terminals of the transistors M26 and M27. Similarly, the capacitance between the third terminal 906 and the fourth terminal 908 is a function of the capacitors C13 and C14, and the transistors M28 and M29. To adjust the effective capacitance (e.g., to implement a varactor as in FIG. 8C) between the third terminal 906 and the fourth terminal 908, the control signal CTL11 is applied to the first and second terminals of the transistors M28 and M29.

With the double-tuned transformer-based bandpass unit 900, the bandpass frequencies are set by the inductor and capacitors values. Insertion loss is set by transformer k-factor and Q values. With the transistors M26 to M29 and CTL11, tunable parallel resistance is able to flatten the Q, which improves consistency for different double-tuned transformer-based units in a transmission line, DRL, or related phase shifter. Also, the double-tuned transformer-based bandpass unit 900 is crosstalk immune due to fields being confined in the proximity of each transformer. In some examples, the transistor M6 to M29 are high voltage devices (e.g., above 5V) to comply with voltage limits. The first and second negative impedance cells 912A and 912B reduce the insertion loss of the double-tuned transformer-based bandpass unit 900. In some examples, the first and second negative impedance cells 912A and 912B are degenerated (i.e., use negative feedback) to boost linearity.

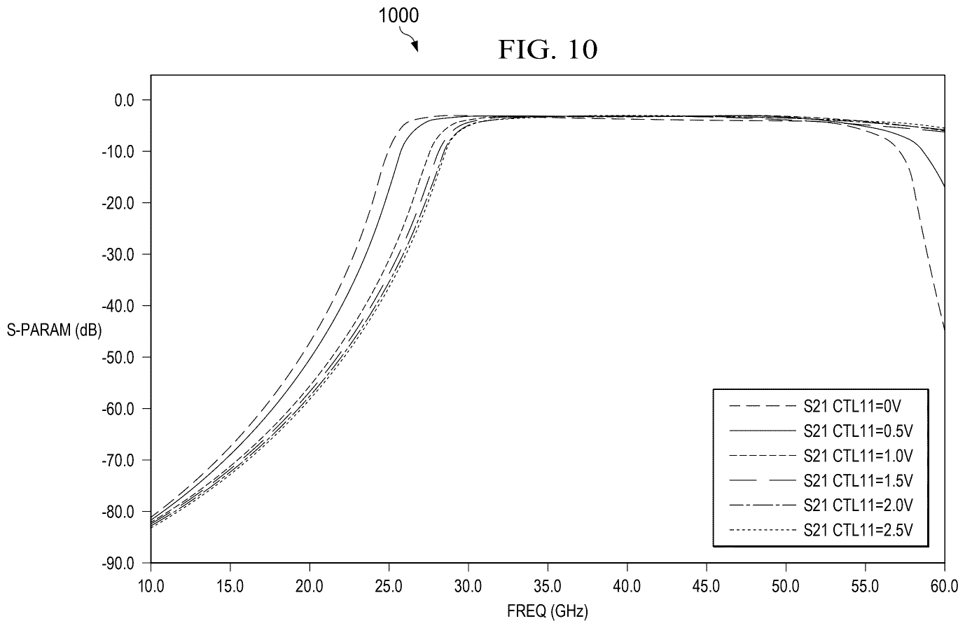

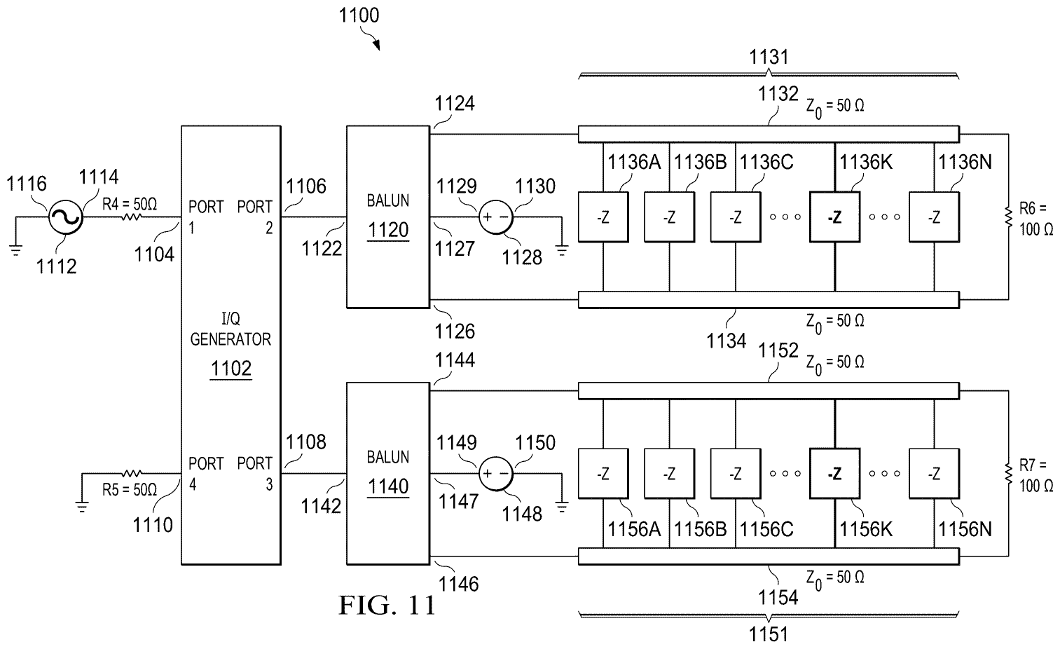

FIG. 10 is a graph 1000 showing S-parameters of a phase shifter as a function of frequency for different control settings. In the example of FIG. 10, S21 waveforms are represented for different values of CTL11 including: CTL11=0V; CTL11=0.5V; CTL11=1.0V; CTL11=1.5V; CTL11=2.0V; and CTL11=2.5V. As CTL11 is adjusted, the effective frequency range of a phase shifter can be adjusted.

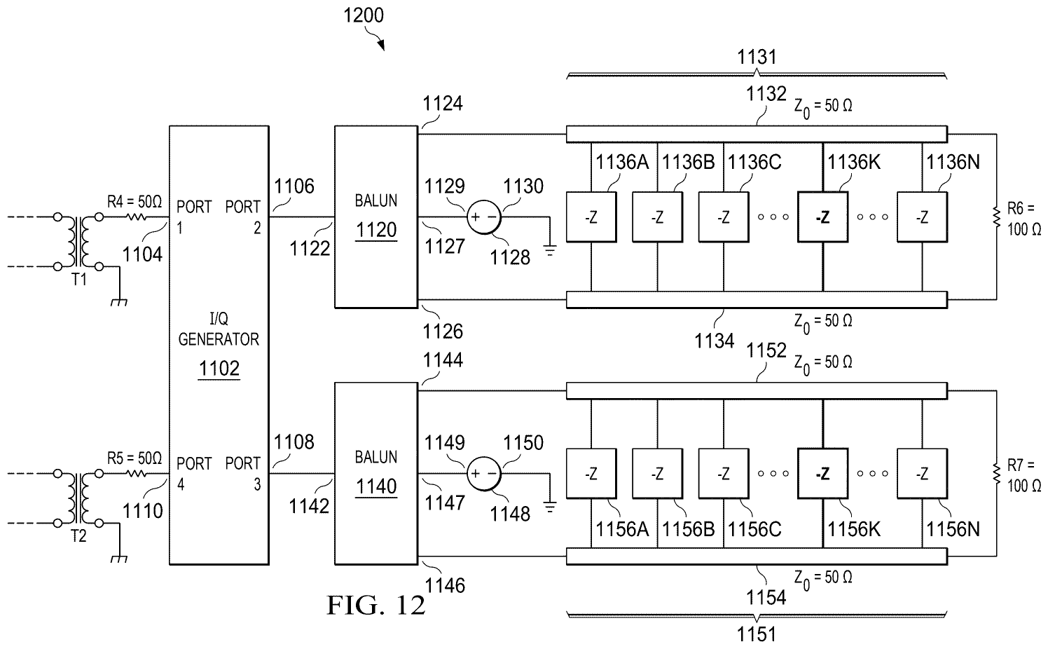

FIGS. 11 and 12 are diagrams showing example phase shifters 1100 and 1200. The phase shifter 1100 of FIG. 11 is a single-ended RTPS and includes an I/Q generator 1102, a first balanced-to-unbalanced (balun) circuit 1120, a second balun circuit 1140, a first transmission line 1131, a second transmission line 1151, an AC source 1112, resistors R4 to R7, a first voltage source 1128, and a second voltage source 1148.

The I/Q generator 1102 has a first terminal 1104, a second terminal 1106, a third terminal 1108, and a fourth terminal 1110. In the example of FIG. 11, the first terminal 1104 is a source terminal, and the fourth terminal 1110 is a load terminal. The second terminal 1106 and the third terminal 1108 are reflective load terminals. To support bidirectional operations, the source terminal and the load terminal can be switched as needed. Also, the second terminal 1106 and the third terminal 1108 may be considered internal terminals of the phase shifter, while the first terminal 1104 and the fourth terminal 1110 are external terminals.

The first balun circuit 1120 has a first terminal 1122, a second terminal 1124, a third terminal 1126, and a fourth terminal 1127. The second balun circuit 1140 has a first terminal 1142, a second terminal 1144, a third terminal 1146, and a fourth terminal 1147. The first transmission line 1131 includes a first impedance line 1132, a second impedance line 1134, and negative impedance cells 1136A to 1136N. In the example of FIG. 11, the first impedance line 1132 has an impedance of 50Ω, the second impedance line 1134 has an impedance of 50Ω, and the transmission line 1131 is matched to resistor R6, which may be 100Ω. The second transmission line 1151 includes a first impedance line 1152, a second impedance line 1154, and negative impedance cells 1156A to 1156N coupled between the first impedance line 1152 and the second impedance line 1154. In the example of FIG. 11, the first impedance line 1152 has an impedance of 50Ω, the second impedance line 1154 has an impedance of 50Ω, and the transmission line 1151 is matched to resistor R7, which may be 100Ω. The AC source 1112 has a first terminal and a second terminal. Each of the resistors R4 to R7 has a respective first terminal and a respective second terminal. The first voltage source 1128 has a first terminal 1129 and a second terminal 1130. The second voltage source 1148 has a first terminal 1149 and a second terminal 1150.

In the example of FIG. 11, the first terminal 1114 of the AC source 1112 is coupled to the first terminal of the resistor R4. The second terminal 1116 of the AC source 1112 is coupled to ground or a ground terminal. The second terminal of the resistor R4 is coupled to the first terminal 1104 of the I/Q generator 1102. The second terminal 1106 of the I/Q generator 1102 is coupled to the first terminal 1122 of the first balun circuit 1120. The second terminal 1124 of the first balun circuit 1120 is coupled to the first impedance line 1132 of the first transmission line 1131. The third terminal 1126 of the first balun circuit 1120 is coupled to the second impedance line 1134 of the first transmission line 1131. The fourth terminal 1127 of the first balun circuit 1120 is coupled to the first terminal 1129 of the first voltage source 1128. The second terminal 1130 of the first voltage source 1128 is coupled to ground or a ground terminal. The first terminal of the resistor R6 is coupled to the first impedance line 1132 of the first transmission line 1131. The second terminal of the resistor R6 is coupled to the second impedance line 1134 of the first transmission line 1131. The negative impedance cells 1136A to 1136B of the first transmission line 1131 are distributed and coupled between the first impedance line 1132 and the second impedance line 1134. In different examples, the first transmission line 1131 may be a lowpass transmission line, a bandpass transmission line, or a double-tuned transformer-based bandpass transmission line.

The fourth terminal 1110 of the I/Q generator 1102 is coupled to the first terminal of the resistor R5. The second terminal of the resistor R5 is coupled to ground or a ground terminal. The third terminal 1108 of the I/Q generator 1102 is coupled to the first terminal 1142 of the second balun circuit 1140. The second terminal 1144 of the second balun circuit 1140 is coupled to the first impedance line 1152 of the second transmission line 1151. The third terminal 1146 of the second balun circuit 1140 is coupled to the second impedance line 1154 of the second transmission line 1151. The fourth terminal 1127 of the second balun circuit 1140 is coupled to the first terminal 1149 of the second voltage source 1148. The second terminal 1150 of the second voltage source 1148 is coupled to ground or a ground terminal. The first terminal of the resistor R7 is coupled to the first impedance line 1152 of the second transmission line 1151. The second terminal of the resistor R7 is coupled to the second impedance line 1154 of the second transmission line 1151. The negative impedance cells 1156A to 1156B of the second transmission line 1151 are distributed and coupled between the first impedance line 1152 and the second impedance line 1154. In different examples, the second transmission line 1151 may be a lowpass transmission line, a bandpass transmission line, or a double-tuned transformer-based bandpass transmission line.

In the example of FIG. 11, the phase shifter 1100 operates to: receive an input voltage (Vᵢₙ); perform phase shift operations on Vᵢₙ using the I/Q generator 1102, the first balun circuit 1120, the second balun circuit 1140, the first transmission line 1131, and the second transmission line 1151; and provide an output voltage (V_{OUT}) responsive to Vᵢₙ and the phase shift operations. In some examples, a first voltage (V₁₊) at the first terminal 1104 of the I/Q generator 1102 is given as: V₁₊=Vᵢₙ∠Φ, where Φ is the phase of Vᵢₙ. In some examples, second voltages (V₂₊ or V₂−) at the second terminal 1106 of the I/Q generator 1102 are given as: V₂₋=0.5*Vᵢₙ∠(Φ+90) and V₂₊=0.5*Γ_{L}Vᵢₙ∠(Φ+90+θ), where θ is the phase shift due to the first transmission line 1131 and the second transmission line 1151. In some examples, third voltages (V₃₊ or V₃₋) at the third terminal 1108 of the I/Q generator 1102 are given as: V₃₋=0.5*Vᵢₙ∠(Φ+180) and V₃₊=0.5*Γ_{L}Vᵢₙ∠(∠+180+θ). In some examples, V_{OUT} at the fourth terminal 1110 of the I/Q generator 1102 is given as: V_{OUT}=V₂₊∠180+V₃₊∠90=Vᵢₙ*Γ_{L}∠(Φ+θ+270). In some examples, the bias voltage for the negative impedance cells 1136A to 1136N is provided by the first voltage source 1128. Also, the bias voltage for the negative impedance cells 1156A to 1156N is provided by the second voltage source 1148. The off-cap (capacitance in an off-state) of the negative impedance cells 1136A to 1136N is absorbed into the first transmission line 1131, and the off-cap of the negative impedance cells 1156A to 1156N is absorbed into the second transmission line 1151.

Relative to other phase shifters, the phase shifter 1100 provides advantages including: bidirectional operation; true time delay; low insertion loss; low amplitude and phase variation; use of bipolar complementary metal-oxide semiconductor (BiCMOS) to overcome switch limitations; and simple calibration. In some examples, calibration includes use of a reference value, comparison of the reference value with the impedance of a negative impedance cell, adjusting control signal (e.g., for a current source or other control circuitry) for a negative impedance cell so that the impedance of the negative impedance cell matches the reference value, and extending the control signal adjustment to other negative impedance cells.

The phase shifter 1200 of FIG. 12 includes the same components as the phase shifter 1100 except the AC source 1112 is omitted and transformers T1 and T2 are added. With the transformers T1 and T2, the phase shifter 1200 is a differential RTPS having a differential input and a differential output.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component and/or a conductor.

A circuit or device described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field-effect transistor (“FET”) such as an NFET or a PFET, a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control terminal and its first and second terminals. In the context of a FET, the control terminal is the gate, and the first and second terminals are the drain and source. In the context of a BJT, the control terminal is the base, and the first and second terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An integrated circuit comprising:
a transmission line including bandpass units, each bandpass unit including:
a first inductor having a first terminal and a second terminal;
a second inductor having a first terminal and a second terminal, the first inductor and the second inductor forming a transformer;
a first capacitor having a first terminal and a second terminal, the first terminal of the first capacitor coupled to the first terminal of the first inductor, and the second terminal of the first capacitor coupled to the second terminal of the first inductor; and
a second capacitor having a first terminal and a second terminal, the first terminal of the second capacitor coupled to the first terminal of the second inductor, and the second terminal of the second capacitor coupled to the second terminal of the second inductor.

2. The integrated circuit of claim 1, wherein the transmission line is a first transmission line and the integrated circuit further comprises:
a second transmission line including bandpass units, each bandpass unit of the second transmission line including:
a first inductor having a first terminal and a second terminal;
a second inductor having a first terminal and a second terminal, the first inductor and the second inductor forming a transformer;
a first capacitor having a first terminal and a second terminal, the first terminal of the first capacitor coupled to the first terminal of the first inductor, and the second terminal of the first capacitor coupled to the second terminal of the first inductor; and
a second capacitor having a first terminal and a second terminal, the first terminal of the second capacitor coupled to the first terminal of the second inductor, and the second terminal of the second capacitor coupled to the second terminal of the second inductor.

3. The integrated circuit of claim 2, further comprising an I/Q generator having a first terminal, a second terminal, a third terminal, and a fourth terminal, the second terminal of the I/Q generator coupled to the first transmission line, and the third terminal of the I/Q generator coupled to the second transmission line.

4. The integrated circuit of claim 3, further comprising:
a first transformer coupled to the first terminal of the I/Q generator; and
a second transformer coupled to the second terminal of the I/Q generator.

5. The integrated circuit of claim 1, further comprising bidirectional phase shifter circuitry, the transmission line coupled to the phase shifter circuitry, the transmission line including negative impedance cells.

6. The integrated circuit of claim 5, wherein the negative impedance cells include an active open switch circuit.

7. The integrated circuit of claim 5, wherein the negative impedance cells include an active short switch circuit.

8. A phase shifter comprising:
reflection-type phase shifter circuitry including:
a first distributed reflective load including first negative impedance cells;
a second distributed reflective load including second negative impedance cells; and
an I/Q generator having a first terminal, a second terminal, a third terminal, and a fourth terminal, the second terminal of the I/Q generator coupled to the first distributed reflective load, and the third terminal of the I/Q generator coupled to the second distributed reflective load.

9. The phase shifter of claim 8, wherein each of the first and second negative impedance cells includes an active open switch circuit, each active open switch circuit including:
a first transistor having a first terminal, a second terminal, and a control terminal; and
a second transistor having a first terminal, a second terminal, and a control terminal, the first terminal of the first transistor coupled to the control terminal of the second transistor, and the first terminal of the second transistor coupled to the control terminal of the first transistor.

10. The phase shifter of claim 9, wherein each active open switch circuit includes a current source having a first terminal and a second terminal, the first terminal of the current source coupled to the second terminals of the first and second transistors.

11. The phase shifter of claim 9, wherein each active open switch circuit includes:
a first current source having a first terminal and a second terminal, the first terminal of the first current source coupled to the second terminal of the first transistor;
a second current source having a first terminal and a second terminal, the first terminal of the second current source coupled to the second terminal of the second transistor; and
a capacitor having a first terminal and a second terminal, the first terminal of the capacitor coupled to the first terminal of the first current source, and the second terminal of the capacitor coupled to the first terminal of the second current source.

12. The phase shifter of claim 11, wherein each active open switch circuit includes a resistor having a first terminal and a second terminal, the first terminal of the resistor coupled to the first terminal of the first current source, and the second terminal of the resistor coupled to the first terminal of the second current source.

13. The phase shifter of claim 11, wherein each active open switch circuit includes:
a third transistor having a first terminal, a second terminal, and a control terminal;
a fourth transistor having a first terminal, a second terminal, and a control terminal, the first terminal of the third transistor coupled to the control terminal of the fourth transistor, and the first terminal of the fourth transistor coupled to the control terminal of the third transistor;
a third current source having a first terminal and a second terminal, the first terminal of the third current source coupled to the second terminal of the third transistor; and
a fourth current source having a first terminal and a second terminal, the first terminal of the fourth current source coupled to the second terminal of the fourth transistor.

14. The phase shifter of claim 8, wherein each of the first and second negative impedance cells includes an active short switch circuit including:
a first transistor having a first terminal, a second terminal, and a control terminal;
a second transistor having a first terminal, a second terminal, and a control terminal, the first terminal of the first transistor coupled to the control terminal of the second transistor, and the first terminal of the second transistor coupled to the control terminal of the first transistor;
a third transistor having a first terminal, a second terminal, and a control terminal;
a fourth transistor having a first terminal, a second terminal, and a control terminal, the first terminal of the third transistor coupled to the second terminal of the first transistor and the control terminal of the fourth transistor, the first terminal of the fourth transistor coupled to the second terminal of the second transistor and the control terminal of the third transistor;
a first current source having a first terminal and a second terminal, the first terminal of the first current source coupled to the second terminal of the first transistor;
a second current source having a first terminal and a second terminal, the first terminal of the second current source coupled to the second terminal of the second transistor;
a third current source having a first terminal and a second terminal, the first terminal of the third current source coupled to the second terminal of the third transistor; and
a fourth current source having a first terminal and a second terminal, the first terminal of the fourth current source coupled to the second terminal of the fourth transistor.

15. The phase shifter of claim 8, wherein each of the first and second negative impedance cells includes an active open switch circuit, each active open switch circuit including:
a transistor having a first terminal, a second terminal, and a control terminal; and
a passive element coupled to the first terminal or the second terminal of the transistor.

16. The phase shifter of claim 8, wherein the first distributed reflective load includes a first double-tuned transformed-based bandpass transmission line, and the second distributed reflective load includes a second double-tuned transformed-based bandpass transmission line, the first and second double-tuned transformed-based bandpass transmission lines including bandpass units, each bandpass unit including:
a first inductor having a first terminal and a second terminal;
a second inductor having a first terminal and a second terminal, the first inductor and the second inductor forming a transformer;
a first capacitor having a first terminal and a second terminal, the first terminal of the first capacitor coupled to the first terminal of the first inductor, and the second terminal of the first capacitor coupled to the second terminal of the first inductor; and
a second capacitor having a first terminal and a second terminal, the first terminal of the second capacitor coupled to the first terminal of the second inductor, and the second terminal of the second capacitor coupled to the second terminal of the second inductor.

17. An apparatus comprising:
a processor;
transceiver circuitry coupled to the processor, and
antenna array terminals coupled to the transceiver circuitry, the transceiver circuitry including:
bidirectional phase shifter circuitry, the bidirectional phase shifter circuitry including:
a first distributed reflective load including first negative impedance cells;
a second distributed reflective load including second negative impedance cells; and
an I/Q generator having a first terminal, a second terminal, a third terminal, and a fourth terminal, the second terminal of the I/Q generator coupled to the first distributed reflective load, and the third terminal of the I/Q generator coupled to the second distributed reflective load.

18. The apparatus of claim 17, wherein each of the first and second negative impedance cells includes an active open switch circuit, and each active open switch circuit includes:
a first transistor having a first terminal, a second terminal, and a control terminal; and
a second transistor having a first terminal, a second terminal, and a control terminal, the first terminal of the first transistor coupled to the control terminal of the second transistor, and the first terminal of the second transistor coupled to the control terminal of the first transistor.

19. The apparatus of claim 17, wherein each of the first and second negative impedance cells includes an active open switch circuit, and each active open switch circuit includes:
a transistor having a first terminal, a second terminal, and a control terminal; and
a passive element coupled to the first terminal or the second terminal of the transistor.

20. The apparatus of claim 19, wherein each of the first and second negative impedance cells includes an active short switch circuit including:
a first transistor having a first terminal, a second terminal, and a control terminal;
a second transistor having a first terminal, a second terminal, and a control terminal, the first terminal of the first transistor coupled to the control terminal of the second transistor, and the first terminal of the second transistor coupled to the control terminal of the first transistor;
a third transistor having a first terminal, a second terminal, and a control terminal;
a fourth transistor having a first terminal, a second terminal, and a control terminal, the first terminal of the third transistor coupled to the second terminal of the first transistor and the control terminal of the fourth transistor, the first terminal of the fourth transistor coupled to the second terminal of the second transistor and the control terminal of the third transistor;
a first current source having a first terminal and a second terminal, the first terminal of the first current source coupled to the second terminal of the first transistor;
a second current source having a first terminal and a second terminal, the first terminal of the second current source coupled to the second terminal of the second transistor;
a third current source having a first terminal and a second terminal, the first terminal of the third current source coupled to the second terminal of the third transistor; and
a fourth current source having a first terminal and a second terminal, the first terminal of the fourth current source coupled to the second terminal of the fourth transistor.
